(19) United States
(12) Patent Application Publication
(10) Pub. No.: US 2007/0278075 A1
(43) Pub. Date: Dec. 6, 2007

(54) Capacitance Type Mems Device, Manufacturing Method Thereof, And High Frequency Device

(76) Inventors: Akihisa Terano, Hachioji (JP); Atsushi Isobe, Kodaira (JP)

Correspondence Address: MILES & STOCKBRIDGE PC, 1751 PINNACLE DRIVE, SUITE 500, MCLEAN, VA, 22102-3833, US

(21) Appl. No.: 10/589,758

(22) PCT Filed: Jul. 29, 2004
(86) PCT No.: PCT/JP04/11219

§ 371 Date: Jun. 11, 2007

(51) Int. Cl. H01P 1/10; H01L 21/20

(52) U.S. Cl. 200/181; 438/393; 257/E21.09

(57) ABSTRACT

A capacitance type MEMS device capable of obtaining favorable switching characteristics relative to high frequency signals, a manufacturing method thereof, and a high performance high frequency device mounting the capacitance type MEMS device are provided. A typical example of the device of the present invention has a conductor layer formed on a dielectric film. The dielectric film is formed on a lower electrode opposed to an upper electrode made of a metal film. The upper electrode vertically moves. The area of a region where the conductor layer formed on the dielectric layer is present in a region where the upper electrode and the lower electrode are opposed is equal to or smaller than the area of the region where the conductor layer formed on the dielectric layer is not present in the opposed region.

### TECHNICAL FIELD

The present invention relates to a capacitance type MEMS (Micro-Electro-Mechanical System) device and a manufacturing method thereof. Further, in another aspect, the present invention relates to a high frequency device mounting the capacitance type MEMS device described above. The capacitance type MEMS device is a device for turning on/off high frequency electric signals by varying the capacitance value. Then, it is useful to electric signals at a high frequency ranging from several megahertz to several terahertz.

### BACKGROUND ART

Heretofore, MEMS devices have been known as fine electromechanical parts for turning on/off electric signals.

Particularly, MEMS devices applied to high frequency switches for turning on/off high frequency signals include, for example, a capacitance type (electrostatic driving type) MEMS device disclosed by J. J. Yao., in TOPICAL REVIEW, “RF MEMS from a device perspective”. J. Micromech. Microeng. 10 (2000) R9-R38 (particularly, R13, FIG. 5) (Document 1), and a capacitance type MEMS switch disclosed by H. A. C. Tilmams., in “RF-MEMS metal contact capacitive switches”, 4^{th} Round Table on MNT for Space, 20/22 May, 2003 (ESTEC, Noordwijk, NL. page 4-page 7) (document 2). They have a function of varying the capacitance value between upper and lower electrodes by vertical movement of the upper electrode due to voltage application.

In the capacitance type MEMS device shown in Document 1, a thin dielectric film is formed on a signal line used as a lower electrode formed on a substrate, and a ground line is formed in parallel on both sides of the signal line. A membrane comprising an integral structure of a metal anchor, a spring and an upper electrode is connected electrically to the ground line. Further, the membrane is formed vertically over a space that is placed on the dielectric film formed on the signal line.

In the structure shown in Document 2, a metal film referred to as a floating metal is formed on the dielectric film above the lower electrode which is positioned below the upper electrode.

The basic operation of the device is as described below. For the two types of the MEMS devices described above, in the case where a DC voltage is not applied between the membrane that functions as the upper electrode and the signal line used as the lower electrode, the MEMS device is in an ON (membrane-up) state due to the space between the membrane and the dielectric film formed on the signal line, and an input signal reaches an output end. when a DC voltage is applied, the membrane is attracted toward the signal line due to an electrostatic force (that is, coulomb force) caused by the potential difference between the membrane and the signal line, and deformed elastically and bent toward the substrate. In the capacitance type MEMS device of Document 1, the upper electrode portion is in a state in contact with the dielectric film on the signal line. On the other hand, in the capacitance type MEMS switch described in Document 2, the upper electrode portion is in a state in contact with the floating metal formed on the dielectric film.

Thus, since both of the two structures form a capacitor structure comprising the membrane, the dielectric film, and the signal line, they are in an OFF (membrane-down) state. In this state, the input signal can not reach the output end. In the structure disclosed in Document 2, however, a capacitance value in the OFF state is obtained more stably than that in the structure of Document 1 due to the effect of the floating metal formed in close contact with the dielectric film. Accordingly, the structure of Document 2 has a feature capable of obtaining better characteristics than the device of Document 1 in view of the switching characteristics for high frequency signals.

The MEMS device using the methods described above is also called an electrostatic driving type MEMS device (switch) in view of the operation principle thereof in addition to the name of the capacitance MEMS device (switch). In the following descriptions of the present specification, the devices called by the plural names described above are considered to be the same unless otherwise specified.

The MEMS switch includes a series connection type switch in which an MEMS device is connected in series with the signal line and a shunt type switch in which it is connected in parallel. In the present specification, a description is made of the shunt type as an example unless otherwise specified. It will be apparent that the invention is applicable to both types of the switches.

### DISCLOSURE OF THE INVENTION

A principal object of the present invention is to provide a capacitance type MEMS device capable of obtaining satisfactory, stable switching characteristics relative to high frequency signals and operating at a low voltage, as well as a manufacturing method thereof. Further, it intends to provide a high performance high frequency device mounting the capacitance type MEMS device according to the invention.

A main embodiment of the capacitance type MEMS device according to the invention is as described below. The capacitance type MEMS device has an insulative substrate, a lower electrode formed on the insulative substrate, a dielectric layer formed on the lower electrode, a conductor layer formed on the dielectric layer, and the upper electrode. The upper electrode is disposed opposed to the lower electrode and arranged with at least a gap between the upper electrode and the conductor layer formed on the dielectric layer. In addition, the upper electrode is controlled whether it is in contact or non-contact with the conductor layer.

In the present invention, the conductor layer on the dielectric layer is necessary to be formed in a region where the upper electrode and the lower electrode are opposed such that the conductor layer on the dielectric layer is present within a part of the opposed area when observed from the direction perpendicular to the insulative substrate. Further, it is required that the area of the region where the conductor layer on the dielectric layer is present within a region where the upper electrode and the lower electrode are opposed be equal to or smaller than the area of the region where the conductor on the dielectric layer is not present within the opposed region.

Further, another embodiment of a capacitance type MEMS device according to the present invention is described below. The capacitance type MEMS device has an insulative substrate, a lower electrode formed on the insulative substrate, a dielectric layer formed on the lower electrode, a conductor layer formed on the dielectric layer, and an upper electrode. The upper electrode is arranged opposed to the lower electrode and at least with a gap placed between the upper electrode and the conductor layer on the dielectric layer. The upper electrode is controlled whether it is in contact or non-contact with the conductor layer. It is required that the conductor layer on the dielectric layer is connected at a desired potential through a resistor to high frequency signals.

In a further aspect, the invention provides a high frequency device having the capacitance type MEMS device described above.

### BRIEF DESCRIPTION OF THE DRAWINGS

FIG. 1A is a plan view for explaining a capacitance MEMS device according to a first embodiment of the present invention.

FIG. 1B is a cross sectional view taken along line B-B′ shown in FIG. 1A.

FIG. 2A is a plan view for explaining another means for solving the problems in conventional techniques.

FIG. 2B is a cross sectional view taken along line B-B′ shown in FIG. 2A.

FIG. 3A is a plan view for explaining a conventional capacitance type MEMS device.

FIG. 3B is a cross sectional view taken along line B-B′ shown in FIG. 3A.

FIG. 4A is an upper plan view for explaining a conventional capacitance type MEMS device.

FIG. 4B is a cross sectional view taken along line B-B′ shown in FIG. 4A.

FIG. 5 is a plan view for explaining another means for solving the subject in the conventional techniques.

FIG. 6 is a plan view for explaining yet another means for solving the subject in the conventional techniques.

FIG. 7A is a plan view for explaining the capacitance MEMS device according to the first embodiment of the present invention.

FIG. 7B is a cross sectional view taken along line B-B′ shown in FIG. 7A.

FIG. 8 is a plan view for explaining a third embodiment of the present invention.

FIG. 9A is a plan view for explaining a capacitance MEMS device according to a fourth embodiment of the present invention.

FIG. 9B is a cross sectional view taken along line B-B′ shown in FIG. 9A.

FIG. 9C is a schematic perspective view for explaining a structure of a membrane in an example shown in FIG. 9A.

FIG. 10A is a plan view for explaining a capacitance MEMS device according to a fifth embodiment of the present invention.

FIG. 10B is a cross sectional view taken along line B-B′ shown in FIG. 10A.

FIG. 11A is an equivalent circuit diagram for a control circuit according to a sixth embodiment.

FIG. 11B is an equivalent circuit diagram for a control circuit according to a seventh embodiment.

FIG. 12A is a cross sectional view showing a membrane-up state in the sixth embodiment.

FIG. 12B is a cross sectional view showing a membrane-down state in the sixth embodiment.

FIG. 13 is an equivalent circuit diagram for explaining a control circuit used for an eighth embodiment.

FIG. 14 is a block diagram for explaining a ninth embodiment.

FIG. 15 is a cross sectional view showing an example of manufacturing steps of a capacitance type MEMS device of the first embodiment.

### BEST MODE FOR CARRYING OUT THE INVENTION

<Consideration on Problems>

Before explaining various embodiments for practicing the invention, problems on the conventional capacitance type MEMS devices, which have been found by the inventors, are described and discussed.

The present inventors at first experimentally manufactured a capacitance type MEMS device having a substantially identical structure with that of Document 1 and evaluated an absolute value of the capacitance and the capacitance ratio in the same switching operation (on/off) as that described above.

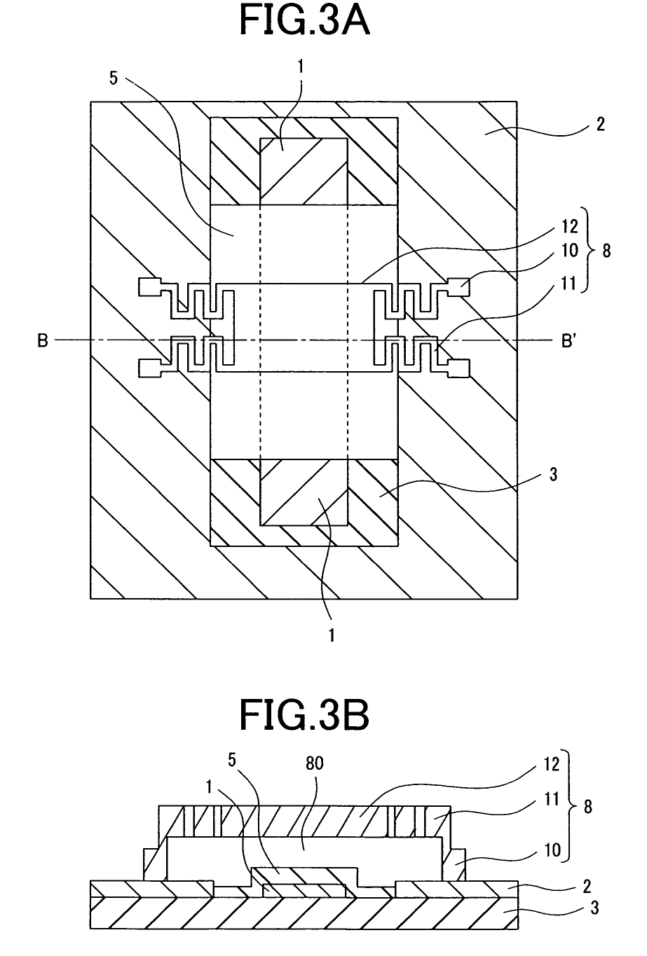

The capacitance type MEMS device experimentally manufactured has a structure shown in FIG. 3A and FIG. 3B. FIG. 3A is a plan view of the device and FIG. 3B is a cross sectional view.

A signal line 1 is disposed on an insulative substrate 3. A ground line 2 is arranged surrounding the signal line 1. A dielectric film 5 is formed covering the signal line 1. An upper electrode 12 is disposed with a gap 80 between the upper electrode 12 and the dielectric film 5. Springs 11 are formed on both ends of the upper electrode 12. A member comprising the upper electrode 12, the springs 11 and the anchors 10 connected with the springs is referred to as a membrane 8.

In the membrane 8, the anchors 10 connected with a ground line 21 (hereinafter referred to as the “earth”), springs 11 each having a meander (corrugated structure), and an upper electrode 12 form an integral structure. The area of an opposed region between the signal line 1 used as the lower electrode formed on a substrate (3) below the membrane 8 and the upper electrode 12 (region where both upper electrode and lower electrode are overlapped as viewed in the perpendicular direction, hereinafter simply referred to as the “opposed region” unless otherwise specified) is 200 micrometers×200 micrometers.

The vertical distance of a space 80 positioned between the upper electrode 12 and dielectric film 5 is about 1.3 micrometers. An aluminum film with a thickness of 0.3 micrometer was used as a material for the dielectric film 5 which formed on a portion of the signal line 1 used as the lower electrode and on a portion of the insulative substrate 3.

Au (gold) with a thickness of 2.5 micrometers was used for the membrane 8. On the other hand, a lamination film comprising a Ti lower layer (0.05 micrometer) and an Au upper layer (gold, 0.5 micrometer thickness) was used for the signal line 1 used as the lower electrode and the ground line 2 connected with the membrane 8.

Further, during the manufacturing process, a sacrificial layer pattern to be removed subsequently was formed below the membrane in order to form the membrane 8 which floats in the air. To facilitate the removal of the sacrificial layer, apertures of 10 micrometers (not illustrated) are formed in the upper electrode 12 at intervals of 20 micrometers at plural positions. The sacrificial layer will be described later.

The material used for the sacrificial layer generally includes a silicon oxide film, a photoresist film, a polyimide film, etc. A polyimide film was used for the manufacture of the capacitance type MEMS device described above.

Using the capacitance type MEMS device with the structure described above, the voltage applied to the signal line 1 was gradually increased from 0 V (earth 2: grounded). As a result, even when a DC voltage of about 6V was applied between the upper electrode 12 and lower electrode 1 and the upper electrode 12 was attracted toward the lower electrode 1 and thus was in contact with the dielectric film 5 (membrane-down), the capacitance value was increased only to a value about three times (about 1.5 pF), compared with the capacitance value obtained in the case where the voltage was not applied between the upper electrode 12 connected to the earth 2 and the lower electrode 1 used as the signal line (about 0.5 pF).

In a calculation based on a simulation with respect to the operation of the capacitance type MEMS device, the result was obtained that the capacitance value increased by about 50 times since the upper electrode 12 is in complete contact with the dielectric film 5 (membrane-down), compared with the case of membrane-up (that is, at 0 V). In the actual experimental manufacture, however, the increase in the capacitance value was extremely small as described above.

With studies on the cause, it was found that, even when a voltage was applied such that the upper electrode 12 and the dielectric film 5 was complete contact with each other, a slight gap (air gap) was formed between both of them.

That is, it is considered that a low-dielectric region was formed between the upper and lower electrodes due to the air gap to decrease the capacitance value.

On the other hand, the structure disclosed in the Document 2 was actually manufactured for experiment. The absolute value of the capacitance and the capacitance ratio of a capacitance value when a DC voltage is applied and a capacitance value when a DC voltage is not applied were evaluated in the same manner as described above.

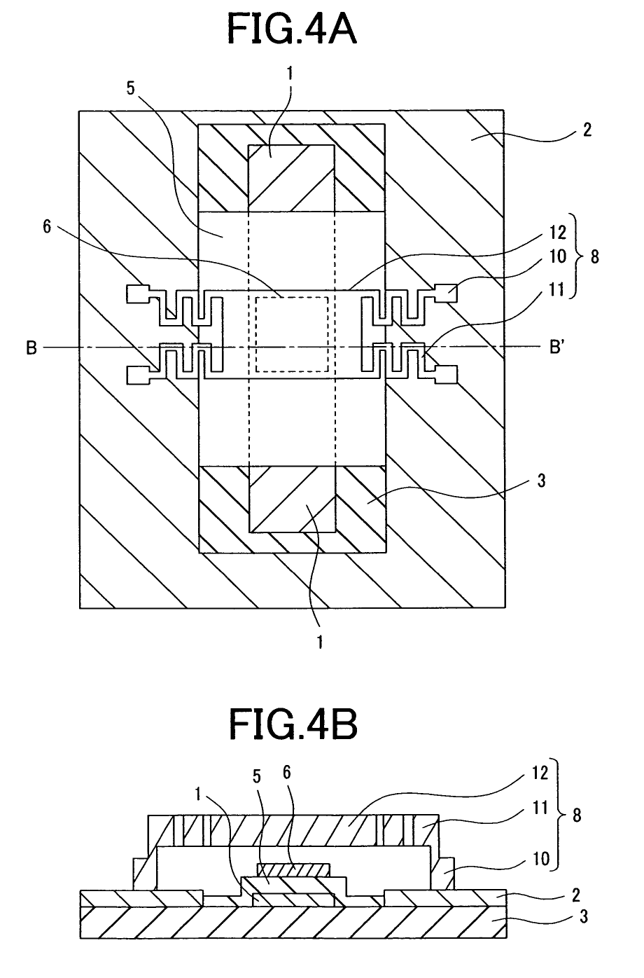

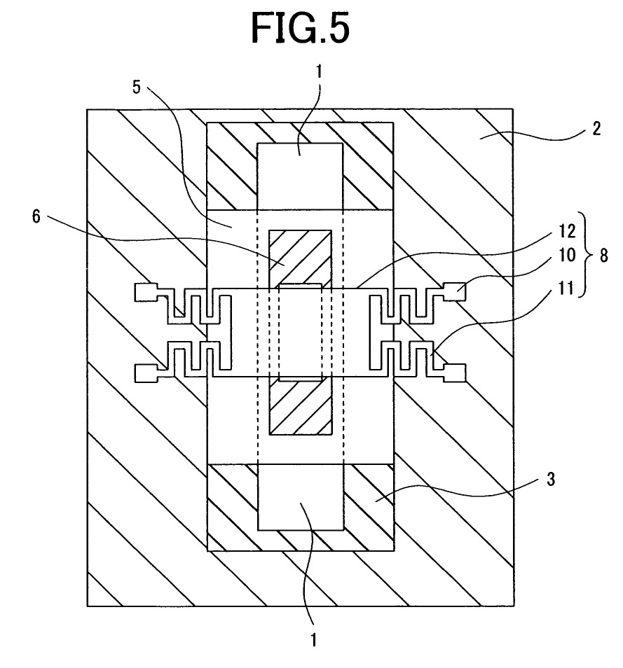

The capacitance type MEMS device experimentally manufactured has a structure shown in FIGS. 4A and 4B. FIG. 4A is a plan view of the device and FIG. 4B is a cross sectional view taken along line BB′.

A signal line 1 used as a lower electrode was disposed on an insulative substrate 3. A ground line 2 was arranged around the signal line 1. In this example, a floating metal (metal film in a floating state) 6 was disposed on the dielectric film 5. An upper electrode 12 was disposed while being in contact with the ground line 2 with a gap 80 placed on the floating metal 6 and on the dielectric film 5. Springs 11 and a membrane 8 connected with the springs are formed on both ends of the upper electrode 12. The membrane 8 included the upper electrode 12, the springs 11 and anchors 10.

In this example, the floating metal 6 not electrically connected with any portion in a stationary state was formed in the structure shown in FIGS. 3A and 3B described above. In this example, the metal film 6 was made of an Au (gold) film with a thickness of 100 nanometers on the dielectric film 5 within the opposed region 81.

The area of the floating metal 6 was smaller than the area of the opposed region 81 which was between both of the electrodes. The area of the floating metal 6 was 180 micrometers×180 micrometers. Each side of the floating metal 6 was 10 micrometers smaller than the four outer peripheral sides of the opposed region 81.

As a result of evaluation using the capacitance type MEMS device having the structure described above, when a DC voltage was applied between the upper electrode 12 and the lower electrode 1 and the upper electrode 12 was attracted toward the lower electrode 1 and then in contact with the floating metal 6 (membrane-down), the capacitance value shows an extremely high capacitance value of 24 pF (about 50 times as much as that upon the application of 0 V).

As an operation voltage, however, a voltage of about 20 V, which is three times as high as that in the case where the floating metal is not present, was required. Further, after repeating the vertical movement of the membrane several times, and then applying the voltage of 20 V for several seconds, the capacitance value between the upper and lower electrodes returned to the initial value (about 0.5 pF).

In this state described above, when the application voltage was returned to 0 V, the capacitance value again increased to 20 pF or more. After several seconds, however, the capacitance value returned to the initial value (about 0.5 pF). This phenomenon is hereinafter referred to as the unexpected phenomenon.

From the foregoing description, it was found that the conventional capacitance type MEMS device having the floating metal 6 described above required a high voltage for the operation of the device especially when applied to a high frequency switch which processes high frequency signals of several hundreds megahertz or higher. In addition, it was found that the switching characteristics were extremely unstable.

<Present Invention and Consideration on the Experimental Result>

As described above, the gist of the present invention is to limit the area ratio of the area of the conductor layer (floating metal) within the opposed region relative to the entire opposed region (the other region being a dielectric film exposure region) to 50% or less, with respect to the capacitance type MEMS device having the floating metal constituting the conductor layer.

Further, another means for solving the problem described above is to connect the conductor layer (floating metal) with a material having a desired potential through a material acting as a resistance relative to high frequency signals with respect to direct current. In this case, the material acting as the resistor relative to high frequency signals is preferably a resistor showing an electric resistance value of at least 1 kΩ or more and less than 1 MΩ, or an inductor showing impedance of at least 1 kΩ or more and less than 1 MΩ relative to the high frequency signals.

The material having the desired potential, while depending on the structures of the devices, is desirably any one of the upper electrode, the ground region (earth), and the control electrode for applying a DC voltage to control the vertical movement of the upper electrode in order to facilitate the manufacture of the device. This can basically prevent charge-up.

The pattern shape of the floating metal is not limited to a specific shape. For example, the region in which the dielectric film is exposed may be ensured by forming an opening having a predetermined shape in the pattern of the floating metal so long as the area ratio with respect to the opposed region is maintained.

Preferably, the springs, the anchors, and the upper electrode constitute an integral structure and are formed of a continuous metal member.

Further, the metal member is preferably formed, for example, of a material mainly comprising at least a metal material of low resistance. In addition, the metal member is desirably formed with any one of an aluminum-containing single layered film, a lamination film of an aluminum-containing film and other metal film, a gold-containing single layered film, a lamination film of a gold-containing film and other metal film, a copper-containing single layered film, and a lamination film of a copper-containing film and other metal film.

Further, the conductor layer on the dielectric film is preferably formed, for example, of any one of the aluminum-containing single layered film, the lamination film of the aluminum-containing film and other metal film, the gold-containing single layered film, a lamination film of the gold-containing film and other metal film, the copper-containing single layered film, and the lamination film of the copper-containing film and other metal film. That is, the conductor layer is generally preferred to be formed with a material mainly comprising a metal material of low resistance.

In consideration of the high voltage operation shown in the conventional techniques described above, in order that the upper electrode is attracted toward the lower electrode by electrostatic force, the electrostatic force needs to be greater than the restoring force of the spring which is in continuous with the upper electrode.

In the case where the floating metal is disposed above the lower electrode through the dielectric film in the structure as described above, the electrostatic force from the lower electrode in that region exerts intensely on the floating metal (the floating metal is at a potential same as the upper electrode: that is, 0 V).

Then, since electrical charges are gradually accumulated in the floating metal by applying a DC voltage continuously, a potential difference is started to be formed between the floating metal and the upper electrode formed on the floating metal. Then, as the potential difference between them increases, the electrostatic force generated between them also increases. Then, the upper electrode is attracted to the floating metal.

In this case, there is a small time lag between the start time of the voltage application and the instance at which electrostatic force generated between the floating metal and the upper electrode formed on the floating metal can attract the upper electrode to the floating metal due to the accumulation of the charges.

Accordingly, only an extremely weak electrostatic force is generated in a wide opposed region between the floating metal and the upper electrode just after the voltage application.

For example, in order to vertically move the upper electrode by changing the voltage for a short time of 1 sec or less, that is, in order that the electrostatic force within the entire opposed region including a wide area for generating the weak electrostatic force may be greater than the restoring force of the spring, the upper electrode should be attracted mainly at a narrow region (an intense electrostatic force is generated) of the outer periphery where the floating metal is not present. In this case, a weak electrostatic force is also generated in the floating metal region. As a result, it is considered that a higher voltage than that in the structure without floating metal is necessary and a voltage as high as 20 V is necessary for the operation of the device having the conventional structure described above.

Now, consideration is made on the unexpected phenomenon described above regarding the capacitance value with respect to the present invention.

When a DC voltage as high as 20 V is applied between the upper electrode and the lower electrode as described above and the upper electrode is in direct contact with the floating metal, then the upper electrode starts to accumulate charges like the floating metal.

Since the potential on the upper electrode is the same as that on the floating metal by continuously applying the DC voltage as described above, the electrostatic force generated so far from the floating metal to the upper electrode is annihilated. As a result, the electrostatic force attracting the upper electrode so far decreases to less than the restoring force of the spring. The upper electrode recedes from the floating metal to decrease the capacitance value. In this case, since the floating metal is insulated electrically, accumulated charges are released only by spontaneous discharge. It takes several tens of seconds for spontaneous discharge.

In the case where the application voltage is abruptly lowered to 0 V in a state where charges are accumulated on the floating metal, a large potential difference is generated between the upper electrode and the floating metal. In this case, the upper electrode is originally grounded to the earth and the potential on the upper electrode returns to 0 V, and the charges are still accumulated in the floating metal. Due to the large potential difference, an electrostatic force larger than the restoring force of the spring is generated between the upper electrode and the floating metal, and the upper electrode is attracted toward and then in contact with the floating metal. As a result, the capacitance value is temporarily recovered.

It is considered that, since the charges accumulated on the floating metal are released rapidly through the upper electrode, the potential on the floating metal returns to 0 V after several seconds, then, the electrostatic force is annihilated, both of them move away from each other by the restoring force of the spring, thus, the capacitance value returned to the initial value.

To confirm the consideration described above, capacitance type MEMS devices having the size and the structure each same as those exemplified in FIGS. 4A and 4B were manufactured with varying the area ratio of a capacitance film region and the floating metal region within the opposed region. With each area ratio, operation voltages were measured, and it was confirmed if the phenomenon occurred.

The size of the opposed region between the upper electrode and the lower electrode of the capacitance type MEMS device used in this experiment was 200 micrometers×200 micrometers, same as the size described above. The sizes of the floating metal were set to 100 micrometers×100 micrometers (25% of the entire portion), 120 micrometers×120 micrometers (36% of the entire portion), 150 micrometers×150 micrometers (56% of the entire portion), and 170 micrometers×170 micrometers (72% of the entire portion). The structures was formed such that the center of the opposed region matched with the center of the floating metal as viewed in the vertical direction.

The five devices for each area ratio were evaluated and the results are collected in Table 1.

TABLE 1

| | | | Change of |
|---|---|---|---|
| | | Operation | capacitance value |
| Size | Area ratio | voltage | Number of occurrence |
| (μm square) | (%) | (V) | (/5 devices) |
| 100 | 25 | 7.2 | 0 |
| 120 | 36 | 8.1 | 0 |
| 140 | 50 | 8.7 | 0 |
| 150 | 56 | 9.0 | 1 |
| 170 | 72 | 16.4 | 5 |

As the floating metal is smaller, the operation voltage is lowered as seen in Table 1. It has been found that the device having the floating metal of 150 micrometer square (56% of the entire portion) operated at a voltage of 9 V, which was about 1.5 times compared with the operation voltage of a device not having the floating metal (=6 V, in the conventional techniques described above). Further, the device having the floating metal of 141 micrometer square (50% of the entire portion) operates at a voltage of 8.7 V.

It is apparent that the unexpected change of the capacitance value generated by continuously applying the DC voltage is dependent on the area ratio of the floating metal relative to the entire opposed area. With the floating metal of 150 micrometer square or more, the unexpected change of the capacitance value occurs. On the other hand, in the case where the size of the floating metal is smaller than 150 micrometer square, the change of the capacitance value does not occur.

For the devices having the floating metal of 150 micrometer square, one device showed the change of the capacitance value. On the other hand, for the devices having a floating metal of 141 micrometer square, there is no change of the capacitance value. Accordingly, it can be said that the area of the floating metal is desirably 50% or less of the entire opposed region.

As an application, a device having the structure as shown in FIG. 5 was prepared and evaluated. The structure shown in FIG. 5 is substantially identical with the structure of FIG. 4A. In FIG. 5, a floating metal 6 is formed on the dielectric film 5 outside the opposed region as well as within the opposed region as a continuous pattern which is contiguous from the opposed region to a region outside the opposed region. In this case, the area ratio of the floating metal in the opposed region relative to the entire opposed region is about 45% as viewed in the perpendicular direction.

As a result, the operation voltage was 9.8 V, and no unexpected change of the capacitance value caused by continuously applying voltage occurred. Further, the capacitance value showed a large value of about 45 pF, which is 90 times as much as the initial value (0.5 pF).

This can be estimated that, due to electrical contact of the upper electrode 12 with the floating metal 6, an opposed area between the floating metal 6 having a wide area and the lower electrode 1 opposed to the floating metal 6 resulted in the capacitance value. In this case, the floating metal 6 was formed on the dielectric film 5 on the lower electrode 12. Further, it can be said that the arrangement of the floating metal in this structure is an excellent method for increasing the capacitance ratio. The capacitance value is a ratio of the capacitance value when the switch is in an ON state and the capacitance value when the switch is in an OFF state.

From the result of the application experiment described above, it has been found that the problems on the conventional techniques can be avoided by setting the area ratio of the floating metal relative to the opposed region within the specified ratio described above (50% or less). Further, it can be said that the pattern arrangement of the floating metal in this structure is one of excellent methods of increasing the capacitance ratio without undesired effects on the electrostatic force exerting between upper and lower electrodes. That is, when the area ratio of the floating metal relative to the opposed region is restricted to 50% or less, a relation of the electrostatic force greater than restoring force of the spring can be maintained even when charges are accumulated on the floating metal.

In the experiment described above, shunt type capacitance type MEMS devices having the same structure and the same size are used in order to easily compare obtained results with those of other devices. In the case of conducting an experiment in which capacitance type MEMS devices with a different size, a different shape of the spring, or a different membrane, different structure are used with varying the area ratio, the substantially same results were obtained.

However, if the above description is correct, since charges in the floating metal are always accumulated, the device operation may become instable when the operation is repeated continuously.

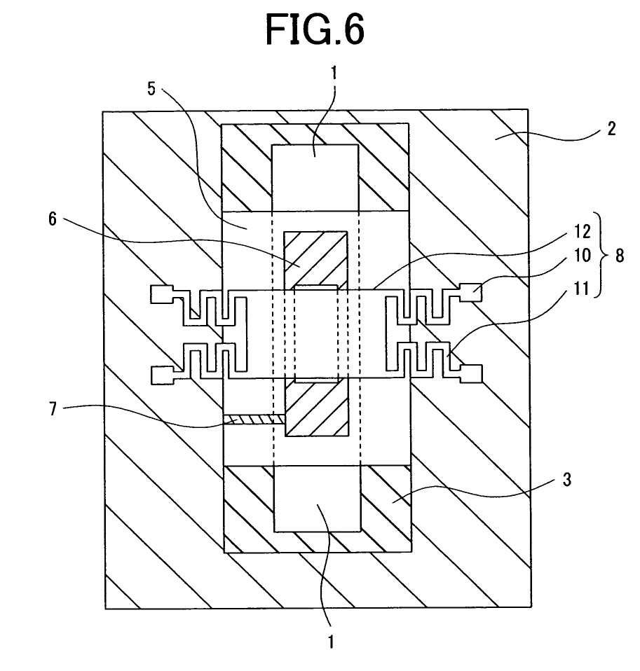

A capacitance type MEMS device with a structure as shown in FIG. 6 was manufactured. In the structure, a resistor pattern 7 with an electrical resistance value of 1 kΩ or more (3.7 kΩ by actual measurement) is disposed between the floating metal 6 and the earth 1 in the device shown in FIG. 5. Then, a DC voltage was applied between upper and lower electrodes in the same manner as in the previous examples. The operation voltage was measured, and it was confirmed if the change of the capacitance value caused by the continuous voltage application occurred. With respect to determining the resistance value of the resistor, the capacitance type MEMS device is mainly used as a switch for high frequency signals. High frequency signals can not pass through a material having a relatively high resistance and an inductor showing a high resistance as impedance. Thus, a metal resistor of 1 kΩ or more was used as an example in this experiment.

The resistor is one of methods of rapidly releasing charges accumulated on the floating metal. As an example, the floating metal is connected with the earth in this structure. This causes the floating metal to be short-circuited with respect to voltage application. The floating metal, however, is in a floating state with respect to high frequency signals. As a result, while the operation voltage was made higher up to 15 V, the unexpected change of the capacitance value was not observed during the voltage application. Further, even when the applied voltage was returned to 0 V, it was confirmed that the capacitance value did not change while keeping the initial value.

The increase of the operation voltage will be described. In the case of the structure described above, since the upper electrode connected to the earth and the floating metal connected, with respect to direct current, through the resistor are always at the same potential, no electrostatic force is generated between the floating metal and the upper electrode. They attract to each other only at the narrow opposed region between the lower electrode region below the region in which the dielectric film is exposed except for the region in which the floating metal is disposed on the dielectric film and the upper electrode opposed to this lower electrode region.

The change of the capacitance value does not occur during the voltage application because the upper electrode and the floating metal attract to each other only at the narrow region where charges are not accumulated. When the applied voltage returns to 0 V, the upper electrode is not attracted toward the floating metal. This is because charges accumulated on the floating metal are rapidly released by connecting the floating metal with the earth through the resistor.

Through the detailed experiments and various considerations described above, it has been found that charges accumulated on the floating metal can be prevented by connecting the resistance element between the floating metal and the earth (or a voltage terminal).

Depending on the resistance value of the resistance element described above, however, on/off switching time may increase and the loss of input signals may increase. In the case of releasing the charges from the floating metal to the earth by using the resistance element, the change of the amount of charges remaining on the floating metal is exponentially in inverse proportion with time.

The time constant dt, where the amount of charges is l/e (e=2.71828), is represented by the product of Cf and Rf. Cf is the capacitance value between the floating metal and the earth, Rf is the resistance value of the resistance element used. Since it is necessary that the time constant dt be smaller than the necessary on/off switching time dtoff, the relationship of dtoff>>dt should be satisfied. In the case of a switch which operates in a GHz band with a low input signal loss, the relationship of Rf<5R to 20 MΩ should be satisfied since Cf needs to range from 5 pF to 20 pF and the relationship of dtoff<0.1 msec is necessary.

In the case of designing a switch which operates with an input signal loss, it is necessary to consider the balance with a Q value of an electronic part (L, filter, etc.) which is connected with the switch. The Q value for L and an filter is about from 20 to 2,000. Particularly, in the case of a high Q filter, high performance is required for the switch.

Since typical dielectric, a SAW filter, has a Q value of 800 or more and a serial resistance of 1Ω or less, the relationship of Rf>800Ω(=1Ω×800) is required.

The above description has been made in the case where the connection destination of the floating metal is the earth. The same effect, however, can be provided in the case of a voltage terminal. Further, if using an inductor instead of the resistance element, the same effect can be provided by changing the impedance over a frequency range in which Rf is operated.

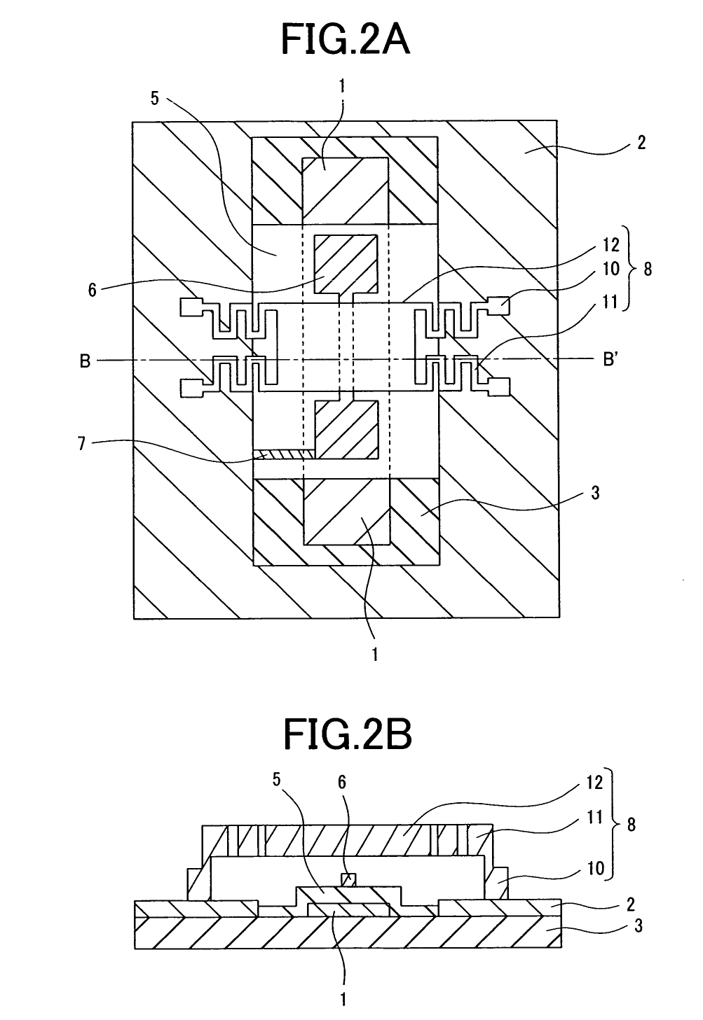

Then, with the aim of lowering the operation voltage of the switch by using the structure in which the resistor is connected as described above, the operation voltage was measured using a capacitance type MEMS device with the area ratio of the floating metal adjusted and the floating metal disposed to the outside of the opposed region. This example is shown in FIGS. 2A and 2B. FIG. 2A is a plan view and FIG. 2B is a cross sectional view taken along line BB′. The shape and the area ratio of the floating metal in this example are different from those in the example of FIG. 6. Thus, other detailed descriptions are omitted. In this example, the area ratio of the floating metal 6 was designed so as to be 15% of the entire opposed region. Briefly speaking, the area of the floating metal 6 in the opposed region was made remarkably small, and the floating metal 6 was extended onto the dielectric film 5 outside the opposed region. Further, the floating metal 6 was short-circuited with the earth 2 through a resistance element of about 2 kΩ.

As a result, the operation voltage was 6.2 V, which is the substantially same value as in the case where the floating metal is not provided. In this case where the floating metal 6 is short-circuited, the capacitance value of 32 pF was obtained, which is about 60 times as much as the initial value.

Based on the foregoing description, the subject of the capacitance type MEMS device using conventional techniques can be solved by using at least one of the following cases. Apparently, both of them can be used.

(1) the area ratio of the floating metal in the opposed region is defined to 50% or less relative to the entire opposed region in the abovementioned conventional structure having the floating metal.

(2) The floating metal itself is connected with a material having a desired potential through a material acting as a resistor relative to high frequency signals with respect to direct current.

Preferably, if the area ratio of the floating metal in the opposed region extremely decreases, for example, to about 15% of the entire opposed region, a capacitance type MEMS device that operates at an operation voltage substantially equal to that of the structure not having a floating metal can be manufactured.

Further, the floating metal may be formed in the region outside the opposed region so long as the limitation described above regarding the area ratio of the formation pattern in the opposed region is maintained, even when the region for forming the floating metal is extended to the region on the dielectric film formed on the lower electrode outside the opposed region. This is because the region in which the floating metal is formed has no effect on the electrostatic force generated in the opposed region. This can increase the capacitance value and the capacitance ratio during operation.

Further, the shape of the floating metal in the opposed region is not particularly limited, and may be formed in any shape.

The material acting as a resistance relative to the high frequency signals indicates, for example, a high resistance material with an electric resistance value of 1 kΩ or more and 1 MΩ or less, or an inductor showing an impedance of 1 kΩ or more and 1 MΩ or less. A material having a desired potential indicates, for example, a ground line, an upper electrode, a lower electrode, a control electrode, and the like. This depends on the structure of the device.

Further, it is preferred that anchors, the springs, and the upper electrode constitute a membrane in an integral structure and form a continuous metal member with a low resistance value.

In this case, the metal member is desirably a single metal film with a low resistance value which is made of gold, aluminum, or copper, or a lamination film of the metal species described above and other metal.

Further, the metal film of low resistance formed on the dielectric film preferably comprises a metal material of low resistance. Particularly, a material capable of remarkably decreasing an ohmic contact with the upper electrode is preferred. Specifically, the metal film of low resistance is preferably a single metal film of gold, aluminum, or copper, or a lamination film of the metal species described above and other metal.

Further, on the surface of the floating metal comprising the metal film of low resistance, upward protrusions comprising the material identical with the floating metal or another metal material of low resistance may be disposed at one or more positions so long as the floating metal is not in contact with the upper electrode in the stationary state (in the case where a voltage is not applied), in addition to the case where the surface of the floating metal is flat.

On the contrary, the same effect can be obtained by disposing downward protrusions at one or more positions to the lower surface of the upper electrode so long as the conditions described above are satisfied.

As the description above, according to the present invention, extremely favorable, stable switching characteristics and isolation characteristics relative to high frequency signals can be obtained. Further, the present invention provides a capacitance type MEMS device which operates at a low voltage with high reliability, as well as a high performance high frequency device mounting the capacitor MEMS device according to the present invention.

In the capacitance type MEMS device of the present invention, when the device is in a OFF state (when a voltage is applied) in the case of acting, for example, as a high frequency switch, the capacitance value can increase by extending and forming the floating metal onto the dielectric film formed on the lower electrode outside the opposed region. In addition, the capacitance value substantially same as a calculation value can be easily attained based on the area of the entire floating metal. This can facilitate the design of the switch device.

Further, since the formation region of the floating metal can be expended to the area outside the opposed region, the upper electrode needs to be in contact with at least one position of the floating metal. Thus, the size of the upper electrode can remarkably decrease compared with that in conventional techniques. This can remarkably suppress the curvature and deformation of the membrane including the upper electrode made of the metal member due to the remaining internal stress.

Also for the floating metal comprising the metal film of low resistance, which is in contact with the upper electrode, the metal film of low resistance including mainly Au, Al, Cu, or the like is used. Thus, the contact resistance and the serial resistance can decrease, resulting in that high frequency signals can be transmitted with an extremely low input signal loss.

With the structure and the characteristics of the capacitance type MEMS device according to the present invention, the device can be also applied to SPnT switches or variable capacitance devices capable of varying the capacitance value which widely ranges by connecting one or more devices according to the present invention in parallel and in series, in addition to the use as the high frequency switch.

Further, since the capacitance type MEMS device according to the present invention can be obtained by adding an extremely small number of the manufacturing processes, the increase of the manufacturing cost can be minimized.

The capacitance type MEMS device according to the present invention can be manufactured easily by a general semiconductor manufacturing process. Thus, the capacitance type MEMS device according to the present invention can be formed on one identical substrate with semiconductor active devices such as FET and bipolar transistors, as well as other passive devices to form one chip. Thus, a module device which is smaller than that of conventional techniques can be easily manufactured.

### VARIOUS EMBODIMENTS

The capacitance type MEMS devices according to the present invention are described more specifically with reference to several preferred embodiments shown in the drawings.

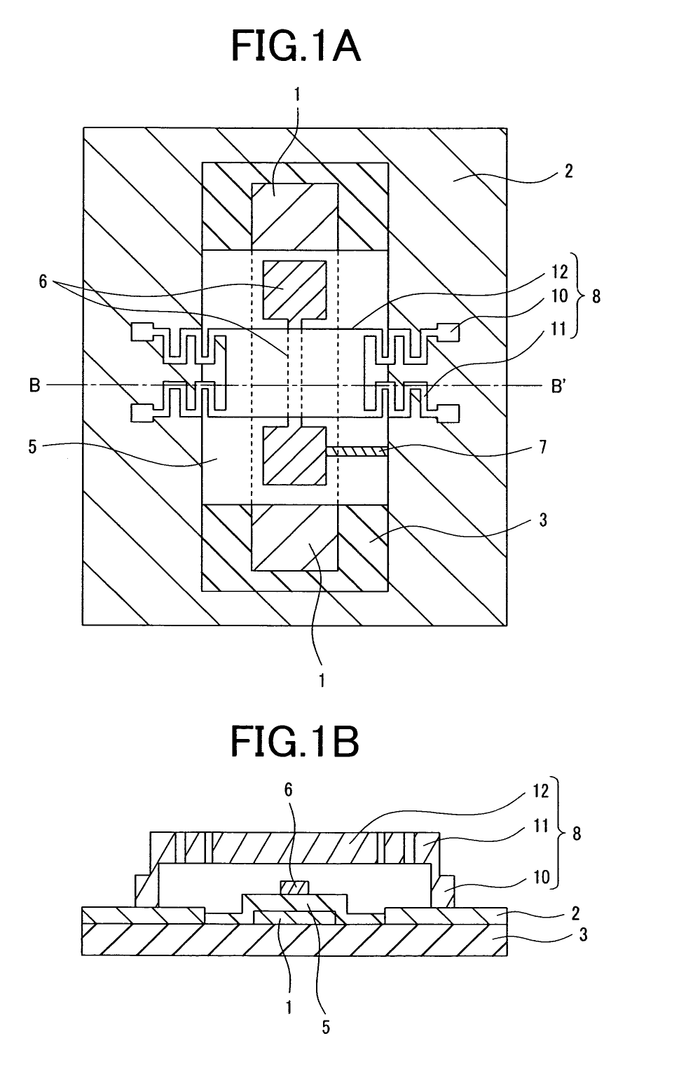

FIGS. 1A and 1B is a schematic view showing a first embodiment of the present invention. FIG. 1A is a plan view of the device and FIG. 1B is a cross sectional view taken along line BB′ shown in FIG. 1A.

A signal line 1 which functions as a lower electrode of the device is formed on an insulative substrate 3, and an earth 2 is formed on the outside of the insulative substrate 3. The insulative substrate 3 is formed, for example, of an insulative material such as a glass substrate, a compound semiconductor substrate, a high resistance silicon substrate, a piezoelectric substrate, or the like. The insulative substrate 3 may also be a semi-insulator substrate or a conductor substrate, each of which the surface is covered with an insulative film represented by silicon oxide.

The signal line 1 and the earth 2 disposed at a predetermined distance with the signal line 1 function as a coplanar type high frequency signal line that extends in the front-back direction of FIG. 1B.

A membrane 8 formed from both sides of the earth 2 over the signal line 1 comprises four anchors 10 connected with the earth 2, four springs 11 each having a meander (corrugated structure) connected with each anchor 10, and an upper electrode 12 to form an integral structure.

A portion on the signal line 1 and a portion on the insulative substrate 3 are covered with a dielectric film 5 made of an alumina film with a thickness of 0.2 micrometers. A floating metal 6 which is made of a metal film of low resistance having a 2-layered Ti/Au structure is formed on the surface of the dielectric film 5 formed on the signal line 1.

The area ratio of the floating metal 6 in the opposed region formed between the signal line 1 and the upper electrode 8 is 15% of the entire opposed region. The floating metal 6 is extended onto the dielectric film 5 formed on the signal line 1 outside the opposed region. The floating metal 6 is connected with the earth 2 through a resistance element 7 having an electric resistance value of 15 kΩ.

The earth 2 is grounded to the earth with respect to high frequency signals, and grounded to the earth (DC potential 0 V) with respect to direct current. Accordingly, the upper electrode 12 is grounded to the earth through the springs 11 and the anchors 10. However, since the floating metal 6 is connected through the resistance element 7 to the earth 2, the floating metal 6 is grounded to the earth only with respect to direct current.

The distance of a space between the upper electrode 12 and the dielectric film 5 is about 0.2 micrometers.

For the membrane 8, Au (gold) with a thickness of 2.5 micrometers is used. For the signal line 1 and the ground line 2, a lamination film having a lower Ti layer (film thickness=0.05 micrometer) and an upper Au layer (gold, 0.5 micrometer thickness) is used.

A polyimide film is used for a sacrificial layer for forming the membrane 8 floating in the air. To easily remove the sacrificial layer, plural through holes of 10 micrometer square are formed in the upper electrode 12 at intervals of 20 micrometers (not illustrated).

The operation voltage of the MEMS device (a voltage when the upper electrode is in contact with the metal film of low resistance) having the structure described above was 6.3 V. The capacitance value of about 48 pF was obtained in this case. This is a value nearly 100 times as much as the capacitance value of about 0.5 pF at 0 V. The substantially same capacitance value as the value determined by calculation based on the opposed area between the floating metal 6 and the signal line 1 was obtained.

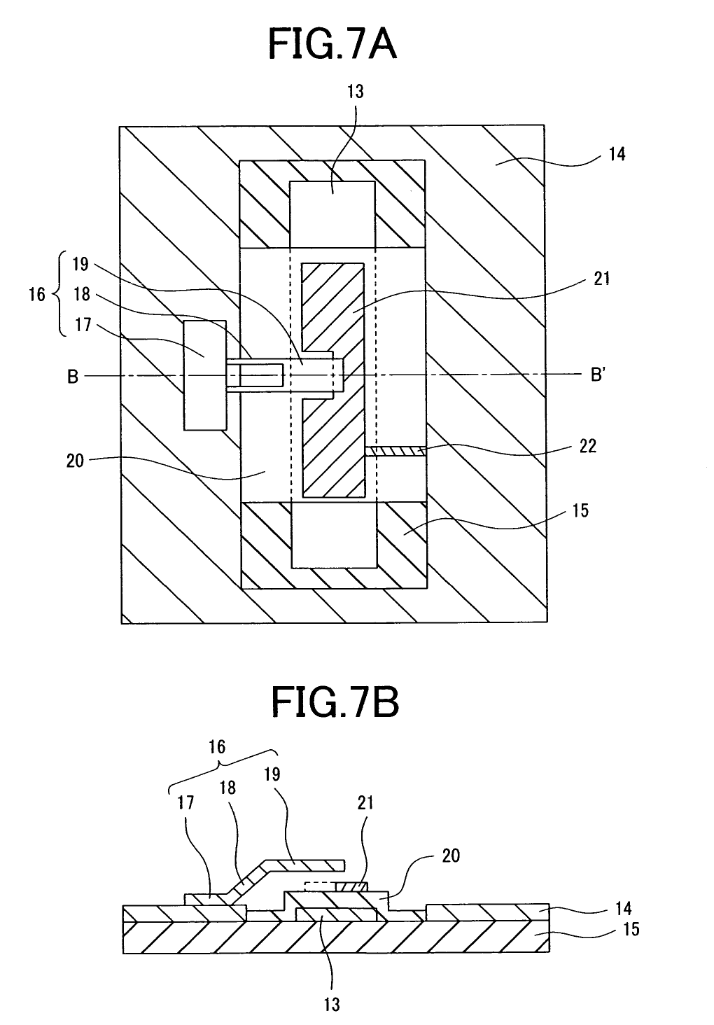

FIGS. 7A and 7B show a schematic view showing a second embodiment of the present invention. This is an example of applying the present invention to a capacitance type MEMS device having a structure in which a cantilever made of a metal member is used. FIG. 7A is a plan view of the device and FIG. 7B is a cross sectional view taken along line BB′ shown in FIG. 7A.

A signal line 13 which also functions as a lower electrode of the device is formed on an Si substrate 15 covered with silicon oxide. A earth 14 is formed outside the Si substrate 15.

A cantilever 16 formed on the earth 14 and formed above a portion of the signal line 13 comprises an anchor 17 connected with the earth 14, a spring 18 connected with the anchor 17 and an upper electrode 19 to form an integral structure. Further, the area of the upper electrode 19 is 20 micrometers×20 micrometers.

A portion on the signal line 13 and a portion on the Si substrate 15 are covered with a dielectric film 20 made of a silicon oxide film with a thickness of 0.15 micrometers, and a flowing metal 21 made of Al is formed on the surface of the dielectric film 20 formed on the signal line.

In this case, the area ratio of the floating metal 21 in the opposed region on the signal line 13 and the upper electrode 19 is 10% of the entire opposed region, and the floating metal 21 extended onto the dielectric film 20 formed on the signal line 13 outside the opposed region. The floating metal 21 is connected with the earth 14 through a resistance element 22 having an electric resistance value of 500 kΩ.

Since the earth 14 is grounded to the earth with respect to high frequency signals and grounded to the earth (DC potential 0 V) with respect to direct current, the upper electrode 19 connected with the earth 14 is also grounded. Since the floating metal 21 is connected through the resistance element 22 to the earth 7, however, the floating metal 21 is grounded to the earth only with respect to direct current. The distance of the space between the upper electrode 19 and the dielectric film 20 is about 0.8 micrometers.

The entire cantilever 16 is made of an Al (aluminum) with a thickness of 2.0 micrometers. For the signal line 13 and the earth 14, a single film of Al (aluminum, 0.4 micrometer film thickness) is used.

A photoresist film is used for the sacrificial layer for forming the cantilever 16 having the upper electrode 19 which is connected to the earth and floats in the air. To easily remove the sacrificial layer, plural through holes of 2 micrometer square are formed in the upper electrode 19 at intervals of 5 micrometers.

The operation voltage of the MEMS device (a voltage where the upper electrode is in contact with the metal film of low resistance) having the structure described above is 1.5 V. The capacitance value of about 24 pF was obtained in this case. This is a value about 120 times as much as the capacitance value of about 0.2 pF at 0 V.

Since the area of the upper electrode 19 in the second embodiment is remarkably smaller than that in the first embodiment, the entire size of the device is also smaller than that of the first embodiment.

The operation voltage, however, is made lower to 1.5 V. Further, the capacitance value obtained was the substantially same as that in the first embodiment. Thus, a capacitance type MEMS device for high frequency which is smaller than that in conventional techniques and has excellent switching characteristics can be manufactured by applying the structure according to the present invention.

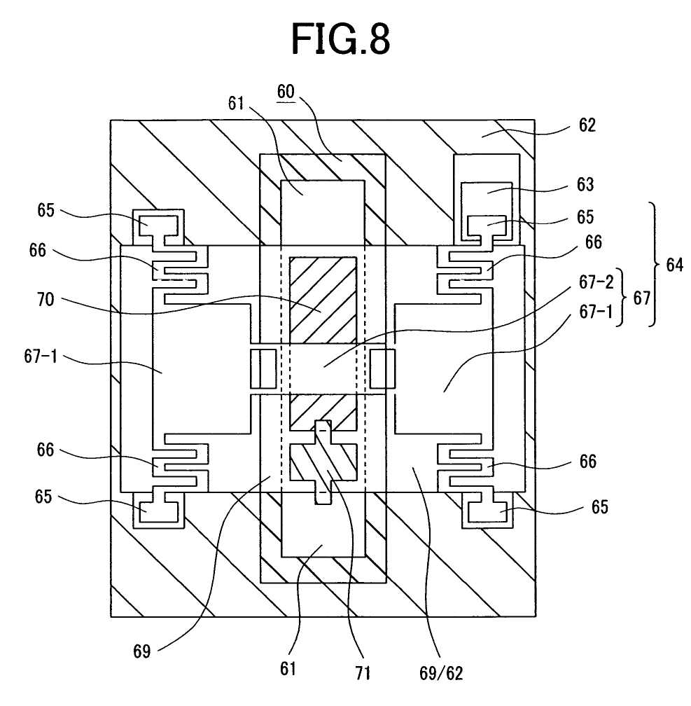

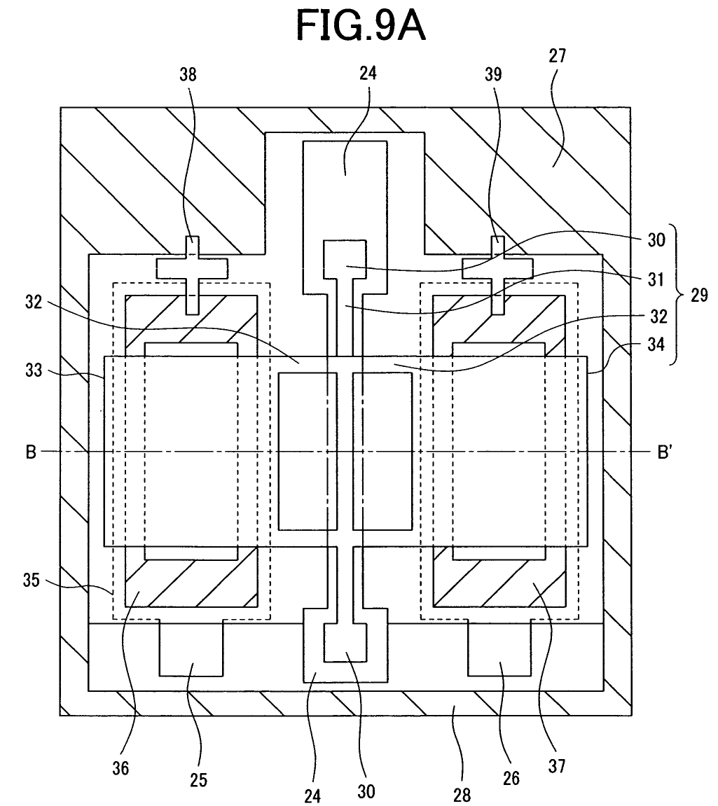

As a third embodiment of the present invention, an example of a capacitance MEMS device provided with a single control terminal independent of the signal line and the earth is shown. FIG. 8 is a plan view showing this example.

A signal line 61 is formed on a glass substrate 60, an earth 62 is formed outside the glass substrate 60. A control terminal 63 not electrically connected with the earth 62 is formed to a portion in the region of the earth 62.

A membrane 64 comprises, anchors 65 connected with the control terminal 63, a spring 66 connected with the anchor 65 and having a meander (corrugated structure), and an upper electrode 67 in which a region 67-1 for generating an electrostatic force between the spring 66 and the earth 62 and a region 67-2 in contact with the floating metal 70 are provided, forming an integral structure.

While the anchors are formed at four positions, only one anchor is connected to the control terminal 63. The other anchors are formed in contact with the glass substrate 60.

A portion of the signal line 61, a portion of the glass substrate 60, and a portion of the earth 62 are covered with a dielectric film 69 made of tantalum oxide with a thickness of 250 nanometers. A floating metal 70 is formed on the dielectric film 69 formed on the signal line 61. The floating metal 70 is connected to the signal line 61 through an inductance element 71 showing the impedance characteristic of about 150 kΩ relative to high frequency signals of about 1 GHz. All of the signal line 61, the earth 62, the control terminal 63, the membrane 64, and the floating metal 70 are made of copper.

In this structure, the region in which the dielectric film 69 is exposed is small in the opposed region between the upper electrode 67 and the signal line 61, and the area ratio of the floating metal 70 relative to the opposed region is about 90%. However, since the electrostatic force relative to the membrane 64 is mainly generated to the earth 62, there is no problem with respect to the operation.

In the structure, an inductance element 71 is disposed in order to prevent accumulation of charges to the floating metal due to the contact of the upper electrode 67.

Since the floating metal can be formed in most of the regions on the dielectric film formed on the signal line, it the floating metal has a feature capable of remarkably increasing the capacitance value obtained upon contact of the membrane to the floating metal by the voltage application to the control terminal.

The example of a shunt connection type device has been described above. The present invention, however, provides the same effect using the series connection type.

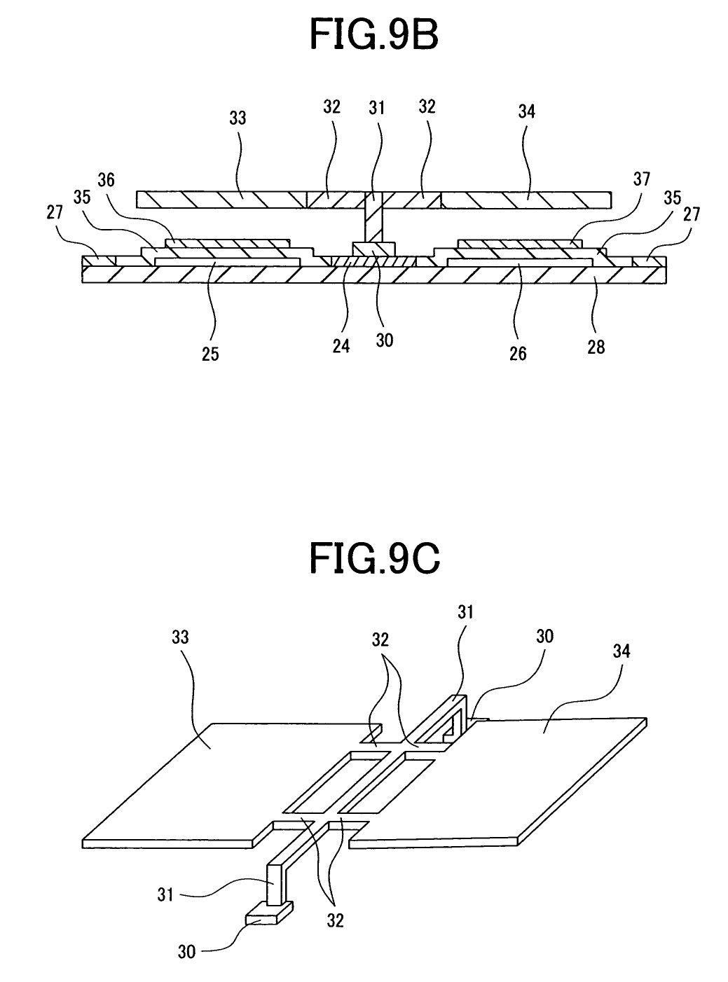

FIGS. 9A to 9C show a schematic view showing a fourth embodiment of the present invention. FIG. 9A is a plan view of the device, and FIG. 9B is a cross sectional view taken along line BB′ shown in FIG. 9A. The drawings show a capacitance type MEMS device with a membrane having a seesaw structure. FIG. 9C is a schematic perspective view for explaining the structure of the membrane.

An input signal line 24 made of Cu (copper) with a thickness of 500 nm is formed on a glass substrate 28. Output signal lines 25 (on the left) and 26 (on the right) are formed on both sides of the input signal line 24. An earth 27 is formed at the periphery thereof.

A membrane 29 made of Au which is connected to the input signal line 24 formed on the glass substrate 28 comprises two anchors 30, a first spring 31 used as a torsion spring for connecting the anchor 30 in the air, a second spring 32 extending onto both right and left sides of the first spring 31, an upper electrodes 33 (on the left side in the drawing) and 34 (on the right side in the drawing) connected on both right and left sides of the second spring 32.

Then, the input signal line 24 is connected with upper electrodes 33 on the left side and 34 on the right side. On the glass substrate 28 formed below both of the upper electrodes, an output signal line 25 (on the left in the drawing) and 26 (on the right in the drawing) made of Cu used as the lower electrode, a dielectric film 35 made of a silicon nitride film, and floating metals 36 (on the left side) and 37 (on the right side) made of a lamination film of Ti/Au are laminated in the order from below. The distance of the space between the floating metals and the upper electrodes is 1.0 micrometer on the right and left sides.

In this case, on the left side, the area ratio of the area of the floating metal 36 relative to the opposed region between the output signal 25 and the upper electrode 33 is 35% of the entire opposed region. On the right side, the same area ratio is obtained. The floating metals 36, 37 extend onto the dielectric film 35 formed on the output signal lines 25, 26 outside the opposed region, respectively.

The floating metals 36, 37 are connected to the earth 27 through inductance elements 38, 39 each showing an impedance of about 300 kΩ relative to high frequency signals at about 1 GHz to 5 GHz.

The capacitance type MEMS device in the structure described above operates by the application of DC voltage between the input signal line 24 and either one of the output signal lines 25, 26 disposed to the right and left sides.

For example, when a voltage is applied relative to the output signal line 26 on the left, the upper electrode 33 is attracted to the line 25 and in contact with the floating metal 36. This forms a capacitor structure. High frequency signals inputted to the input signal line 24 are outputted through the capacitor from the output signal line 25 on the left. Since the upper electrode 34 on the opposite side leaps upward, isolation between the output signal line 26 and the upper electrode 34 increases.

On the contrary, when voltage application on the left is stopped and a voltage is applied relative to the output signal line 26 on the right, the upper electrode 33 on the left recedes from the metal film 36 of low resistance and returns to the original position. Then, the upper electrode 34 on the right is attracted to the output signal line 26 on the right and is in contact with the floating metal 37 on the right and a high frequency signals are outputted in this case from the output signal line 26 on the right. In this case, since the upper electrode 33 on the opposite side leaps upward, isolation between the signal line 25 and the upper electrode 33 increases.

According to the embodiment described above, the capacitance type MEMS device of the fundamental invention is of a structure generally referred to as an SPDT switch capable of selectively switching two channels relative to one signal line. This embodiment can provide a push-pull type one-input two-output changing switch for high frequency signal, which is with a low input signal loss and excellent in isolation characteristic, reflecting the effect of the invention.

While description has been made for the capacitance type MEMS device according to the invention in the case of providing the inductance element or the resistance element inside the device, a same effect can also be obtained by connecting the floating metal to the resistance element or the inductance element formed to the outside of the device.

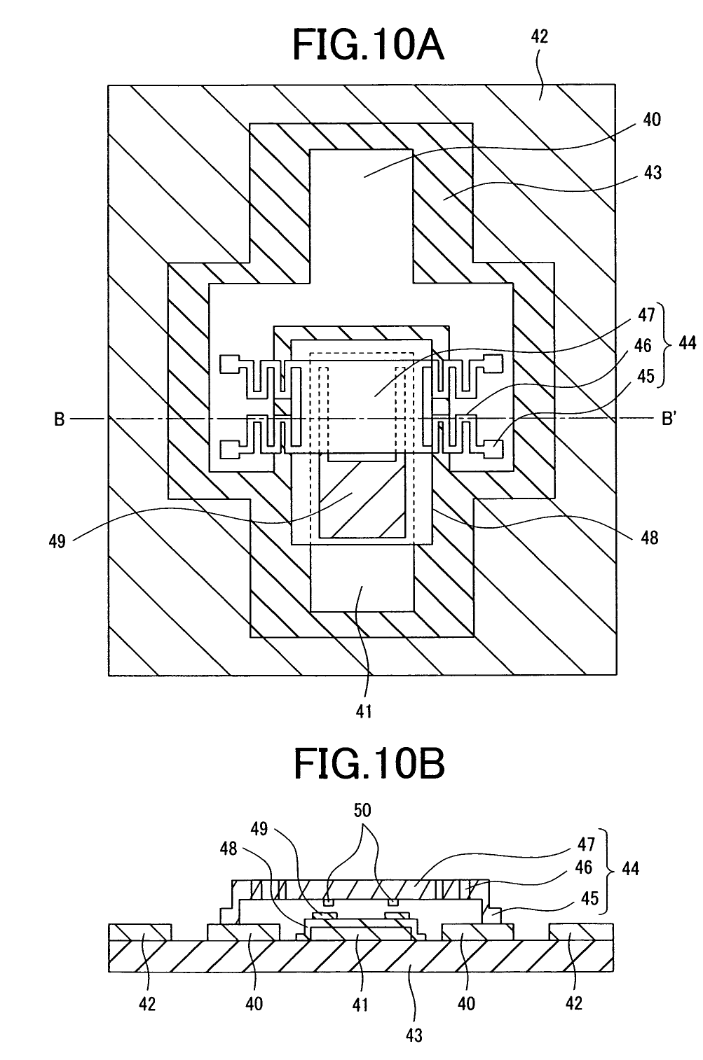

FIG. 10A and FIG. 10B show a schematic view showing a fifth embodiment of the present invention. FIG. 10A is a plan view of the device, and FIG. 10B is a cross sectional view taken along line BB′ shown in FIG. 10A. This embodiment has a membrane having the substantially same structure as that described in the first embodiment. However, this is an example of applying the invention to an on/off switch having a series connection type. The series connection type has a mechanism in which the signal line is divided into the input side and the output side, a voltage is applied between the input side and the output side. A high frequency signal flows to the output side when the membrane is in contact with a metal film of low resistance.

An Al input signal line 40 is formed on an Si substrate 43 covered with silicon oxide, and an output signal line 41 of Al is formed inside a region of the line 40 at a predetermined distance. The region of the line 40 is in a turned square U-shape. Then, an earth 42 is formed at the periphery of the line 40.

A membrane 44 connected to the region of the input signal line 40 and formed over the output signal line 41 comprises four anchors 45, four springs 46 each having a meander (corrugated structure), and an upper electrode 47, forming an integral structure. The region of the input signal line 40 is in a turned square U-shape. A portion on the output signal line 41 and a portion on the Si substrate 43 are covered with a dielectric film 48 formed of a tantalum oxide film, and a floating metal 49 formed of Au and having an opening is formed to the surface of the dielectric film 48 formed on the output signal line 41. Downward protrusions 50 made of Au are formed on the lower surface of the upper electrode 47 at several positions.

In this case, the area of the floating metal 49 in the opposed region between the output signal line 41 and the upper electrode 47 is 15% of the entire opposed region, and the floating metal 49 extending from the opposed region is formed on the dielectric film 48 formed on the output signal line 41 outside of the opposed region.

Since a distance of the space between the upper electrode 47 and the floating metal 49 is about 1.0 micrometer and the protrusion 50 formed on the lower surface of the upper electrode 47 has a height of about 0.3 micrometers. The distance from the top end of the protrusion 50 to the floating metal 49 is 0.7 micrometers.

For the membrane 44, Cu (copper) formed by plating and having 1.5 micrometer thickness is used. For the input signal line 40, the output signal line 41, and the earth 42, a single film of Al (0.6 micrometer thickness) is used.

For a sacrificial layer for forming a membrane floating in the air, a polyimide film having photosensitivity is used. To remove the sacrificial layer, a wet process using an exclusive peeling solution is used. As the final process, a rapid drying treatment using gaseous carbon dioxide is used.

In the MEMS device having the structure described above, when a voltage is applied between the input signal line 40 and the output signal line 41, the upper electrode 47 connected to the input signal line 40 is attracted to the output signal line 41 and in contact with the metal film 49 of low resistance to form a capacitance structure. In this case, high frequency signals inputted to the output signal line 40 flow through the capacitor to the output signal line 41.

In the embodiment described above, a resistance element or the like for releasing charges accumulated on the floating metal is not disposed. Since the area ratio of the floating metal relative to the opposed region is sufficiently small as 15%, however, the device properly operates as a switch without any trouble.

According to the embodiment described above, a capacitance type MEMS device for high frequency signal with an extremely small loss of input signals and having favorable transmission characteristics can be provided.

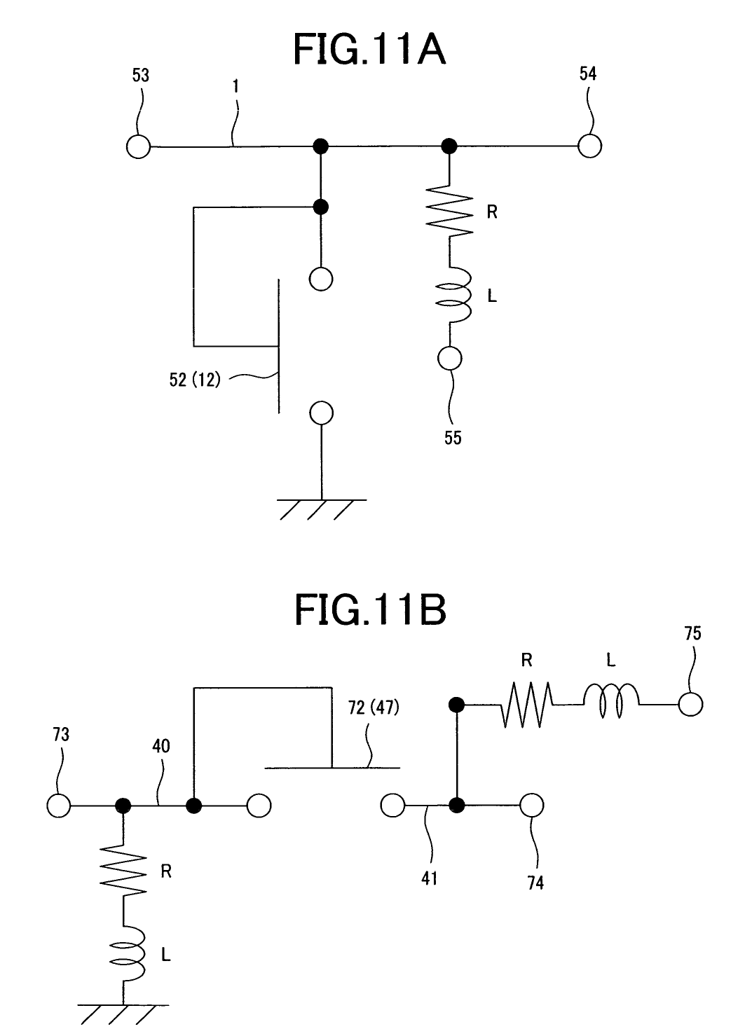

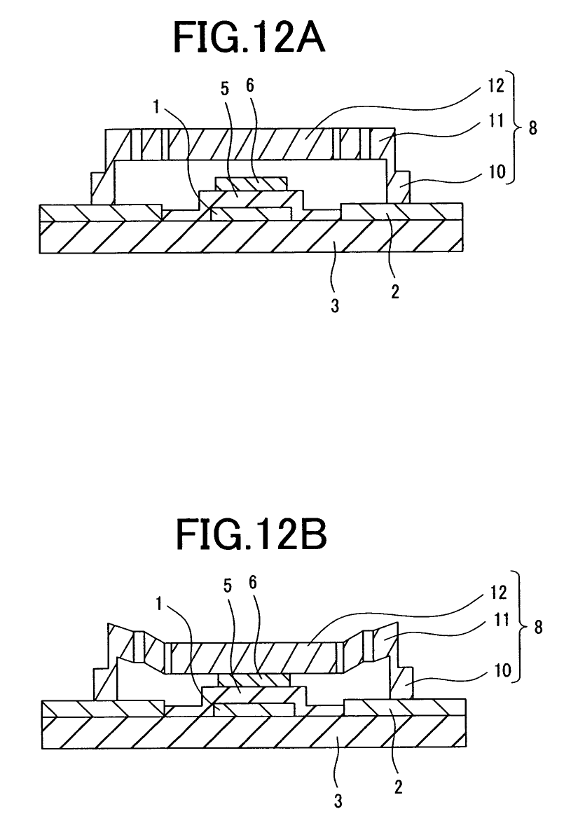

A high frequency device according to a sixth embodiment of the present invention is described. FIG. 11A shows an equivalent circuit diagram for the MEMS device and a control circuit in the case where the capacitance type MEMS device of the present invention described in the first embodiment (shown in FIG. 1A and FIG. 1B) is applied to an on/off switch for high frequency signals as a high frequency device mounting the capacitance type MEMS device of the present invention. A signal line 1 and an upper electrode 12 of the MEMS device are shown like a circuit. FIG. 12A and FIG. 12B are a cross sectional view of the MEMS device showing the up/down states of the membrane respectively in this embodiment. Each of the portions in the cross sectional views are shown with the same reference numerals as those in the first embodiment.

The upper electrode 12 of the MEMS device functions as a high frequency switch 52 of the present invention connected in parallel with the signal line 1. Reference numerals 53, 54 are an input terminal and an output terminal to the signal line 1, respectively. The signal line 1 used as the lower electrode floats in the air with respect to a DC voltage. A control terminal 55 is connected to the signal line 1 through a resistor R and an inductance L showing a high impedance relative to high frequency signals. That is, when a DC voltage for control is given to the control terminal 55, the DC voltage is applied through the inductance L and the resistance R to the signal line 1.

In the case where the DC voltage is not applied to the signal line 1 (DC potential: 0 V), the upper electrode 12 is mechanically held by the spring 11. Accordingly, since the upper electrode 12 sufficiently recedes from the signal line 1, a capacitance value between the upper electrode 12 and the signal line 1 is extremely small (membrane-up, capacitance value: about 0.5 pF). In this case, high frequency signals flowing through the signal line 1 are transmitted from the input terminal 53 to the output terminal 54 with a low signal loss (in the ON state of the switch).

In the case where the DC voltage is applied to the signal line 1, an electrostatic force is generated between the upper electrode 12 and the signal line 1. In the case where the electrostatic force is larger than the restoring force of the spring, the upper electrode 12 is in contact with the floating metal 6 formed on the dielectric film 5 in a manner as if it were bonded (membrane-down, capacitance value=about 28 pF) (in the OFF state of the switch).

In the OFF state, the upper electrode 12 is in electrical contact with the floating metal 6. This constitutes a capacitor comprising the floating metal 6 connected through the upper electrode 12, the dielectric film 5, and the signal line 1. Thus, the signal line is in a state equivalent with that grounded to the earth at a high frequency. Accordingly, most of the high frequency signals flowing from the input terminal 53 to the signal line 1 are reflected at a portion where the floating metal 6 in contact with the upper electrode 12 is in contact with the dielectric film 5, the signals hardly reach the output terminal 54.

Since the electrostatic force between the upper electrode 12 and the signal line 1 is continuously maintained by the region 14, the capacitor structure is continuously maintained unless application of the voltage is stopped.

Then, a high frequency device according to a seventh embodiment of the present invention will be described. FIG. 11B shows an equivalent circuit diagram of a MEMS device and a control circuit when the capacitance type MEMS device having the series connection type of the present invention described in the fifth embodiment (illustrated in FIG. 10A and FIG. 10B) is applied to the same switch as that described above. An input signal line 40 and an output signal line 41 are shown as a circuit. Reference numerals 73, 74, and 75 represent an input terminal, an output terminal, and a control terminal, respectively.

The upper electrode 47 connected with the input signal line 40 functions as a high frequency switch 72 of the present invention connected in series with the output signal line 41. In this case, the output signal line 41 is connected with a control terminal 75 through a resistance R and an inductance L showing a high impedance relative to high frequency signals. That is, when a DC voltage is applied to the control terminal 75, the DC voltage is applied through the inductance L and the resistance R to the output signal line 41.

In the case where the DC voltage is not applied to the output signal line 41 (DC potential 0 V), since the output electrode 47 recedes sufficiently from the output signal line 41, the inputted signals do not reach the output signal line 41 (membrane-up).

In the case where the DC voltage is applied to the output signal line 41, an electrostatic force is generated between the upper electrode 47 and the output signal line 41. In this case, since the upper electrode 47 is attracted and in contact with the floating metal 49 (membrane-down), it constitutes a capacitor comprising the floating metal 49 connected through the upper electrode 47, the dielectric film 48, and the output signal line 41. Thus, the inputted signals can reach the output signal line 41.

According to this embodiment, the high frequency switch mounting the capacitance type MEMS device of the present invention can provide extremely favorable switching characteristics to high frequency signals.

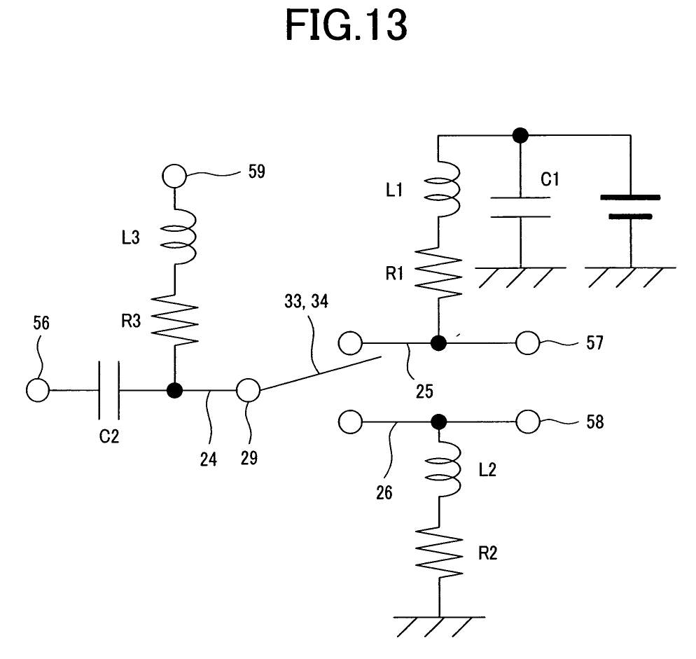

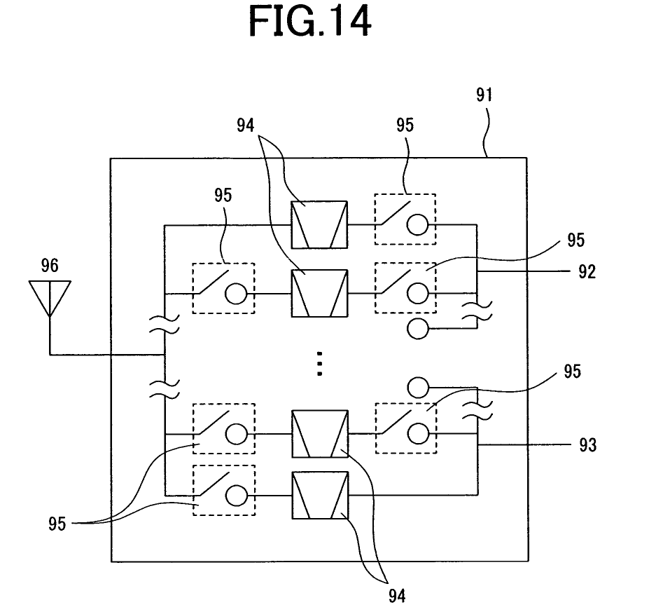

A high frequency device according to an eighth embodiment is to be described. This is an example of applying the capacitance type MEMS device of the invention described in the fourth embodiment (shown in FIG. 9A and FIG. 9B) to a switch capable of switching one input signal into two channels. FIG. 13 shows an equivalent circuit diagram of the MEMS device and a control circuit. In FIG. 13 identical, reference numerals are used for portions identical with those in FIG. 9A and FIG. 9B. Reference numeral 24 denotes an input signal line and reference numerals 25 and 26 denote an output signal channel on the left and an output signal line on the right, respectively. Reference numeral 29 denotes a membrane; 33 and 34, an upper electrode on the left and the upper electrode on the right, respectively; 56, an input terminal; 57 and 58, an output terminals; and 59, a control terminal.

In this embodiment, the membrane 29 is not connected to the earth but connected through the input signal line 24 to the input signal line 56. Then, either of the following operations is performed: an operation of connecting the upper electrode 33 on the left of the membrane 29 to the output signal line 25 with respect to high frequency signals and connecting to the output terminal 57 thereof; or connecting the upper electrode 34 on the right with an output signal line 26 with respect to high frequency signals and connecting to the output terminal 58 thereof.

The voltage of an output terminal 57 is +3 V with respect to direct current through resistance R1 and an inductor L1 for blocking high frequency signals. On the other hand, the output terminal 57 is grounded to the earth with respect to direct current through a resistance R2 and an inductance L2 for blocking high frequency signals. A capacitance C1 is used for grounding the terminal at DC 3 V to the ground with respect to high frequency signals. The membrane 29 floats with respect to direct current by the capacitance C2 A control voltage is applied to the control terminal 59 through a resistance R3 and an inductance L3 for blocking high frequency signals to the control terminal 19. Accordingly, in the case of applying 5 V to the control terminal 59, the input terminal 56 is connected with the output terminal 58 with respect to high frequency signals. In the case where 0 V is applied to the control terminal 59, the input terminal 56 is connected to an output terminal 57.

In the eighth embodiment described above, with the excellent isolation characteristics in the OFF state which is a feature of the capacitance type MEMS device applied, a 1-input 2-output changing switch with a low signal loss and with remarkably decreased signals to the off line can be attained by a single push-pull type capacitance type MEMS device.

FIG. 14 is a block diagram for explaining a ninth embodiment.

This is an example of a high frequency device mounting a capacitance type MEMS device of the present invention, which is a high frequency filter module used, for example, in a mobile phone, etc.

In FIG. 14, high frequency filters 94 are arranged on a substrate 91. An antenna 96 is connected with the substrate 91. Connection portions 92, 93 are connected with a receive system and a transmission system on the opposite side, respectively. In this case, switches are disposed at least to the front side or back side, or both of the front and back sides of the high frequency filters 94. An embodiment of mounting a switch based on the structure shown in the seventh embodiment, or a switch based on the structure shown in the sixth embodiment of the present invention as the switch is used.

Favorable switching characteristics of the present invention can be obtained by mounting a plurality of filters 94 and the capacitance type MEMS device 95 of the present invention. With these characteristics, it is possible to input signals in a plurality of frequency ranges received from the antenna into a desired connection channel with a low signal loss and a low noise level. On the other hand, it is possible to output signals in a plurality of frequency ranges with a low signal loss and a low noise level. Further, it has an advantage capable of remarkably decreasing output signals which turn to the side of input signals.

The capacitance type MEMS device of the present invention is not restricted with respect to the material for the substrate and can be manufactured by general semiconductor manufacturing techniques. Thus, the high frequency filter and the capacitance type MEMS device of the present invention can be manufactured on the same substrate material as that of the filter and can be formed in one chip together with other passive devices.

Further, in the equivalent circuit shown in the sixth embodiment and the seventh embodiment of the present invention, it is also possible that they can be manufactured on one identical substrate together with a logic IC comprising active devices such as Si-MOSFET for transmitting control signals from the control terminal into one chip for the same reason as described above.

That is, the capacitance type MEMS device of the present invention can be manufactured together with active devices or other passive devices on one substrate by using general semiconductor manufacturing techniques.

This can provide a high frequency device which significantly decreases in size compared with a conventional device that mounts other devices individually on the mounting substrate.

In view of the structure and the characteristics of the capacitance type MEMS device of the present invention, it is be apparent that the device can be applied also to SPNT switches or variable capacitance devices capable of varying the capacitance value in a wide range by connecting and arranging one or more devices in parallel and series, in addition to the high frequency switch described above.

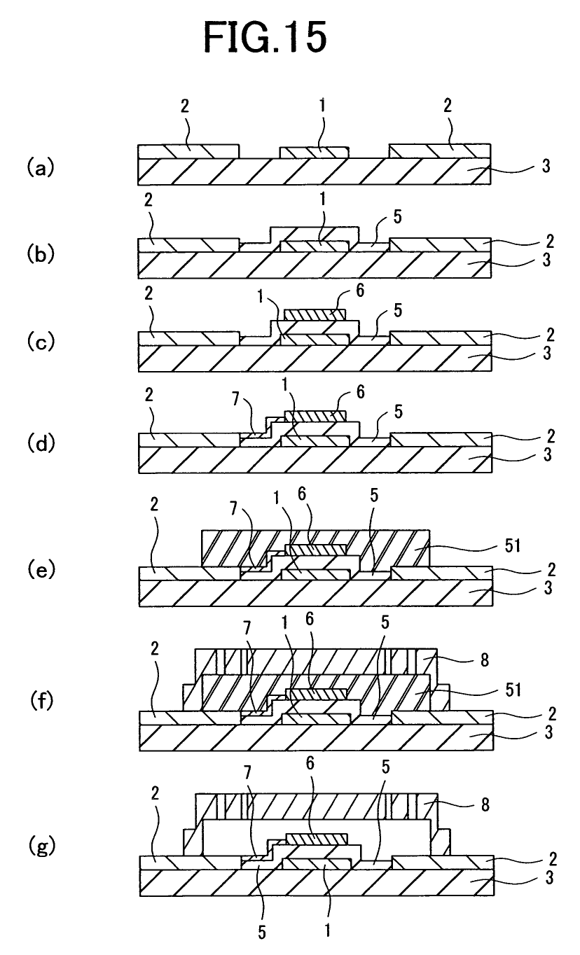

FIG. 15 shows a method of manufacturing an MEMS device according to the present invention.

A method of manufacturing a capacitance type MEMS device according to the first embodiment shown in FIG. 1 is shown as an example. Those according the other embodiments can also be manufactured in accordance with this method.

A two-layered resist pattern for lift-off process, in which a signal line 1 and an earth 2 are reversed, is formed on an insulative substrate 3. Then, Ti with a thickness of 0.05 micrometers is deposited on a first layer, and Au (gold) which a thickness of 0.5 micrometers is deposited on a second layer by using an electron beam vapor deposition method. Then, unnecessary metal film and resist are removed by using a well-known lift-off process to form a pattern of the signal line 1 and a pattern of the earth 2 (FIG. 15(a)).

Then, an alumina film with a thickness of 0.2 micrometers is deposited using a sputtering process. After the deposition, pattern formation is applied by using well-known photolithography. Then, a region in which the alumina film is not masked is removed by etching to form a pattern of a dielectric film 5 only to a desired region (FIG. 15(b)).

Then, a two-layered resist pattern for list off process, on which only the desired region on the signal line is opened, is formed by using the well-known photolithography. Ti with a thickness of 0.05 micrometers is deposited on the first layer and Au (gold) with a thickness of 0.2 micrometers is deposited on the second layer are deposited by using the electron beam vapor deposition method. Then, unnecessary metal film and resist were removed by using the well-known lift off process to form a pattern of a floating metal 6 having a desired shape (15(c)).

Then, a two-layered resist pattern for lift off process, on which only a desired region above the insulative substrate is opened, is formed by using the well-known photolithography. Then, unnecessary metal film and resist are removed by using the well-known lift off process to form a pattern of a resistance element 7 having a desired shape (FIG. 15(d)).

Then, after forming a polyimide film over the entire surface of the insulative substrate 3 by rotational coating, a sacrificial layer pattern 51 comprising a polyimide film opened only for a desired region is formed by using well-known photolithography and etching. The thickness of the polyimide film is controlled such that the film thickness after curing by high temperature baking is 1.2 micrometers (FIG. 15(e)).

Then, an Au film with a thickness of 2.5 micrometers is deposited on the entire surface of the insulative substrate 3 by using the well-known electron beam vapor deposition method. Then, a membrane 8 is formed by using well-known photolithography and Ar⁺ ion milling (FIG. 15(f)).

Finally, the capacitance type MEMS device of the present invention is completed by removing the sacrificial layer 51 by chemical dry etching (FIG. 15(g)).

If it is difficult to prepare the resistance element or the inductor with other devices on one substrate, a lead line pattern may be formed from the floating metal and connected with an external resistance element or an inductance element in the mounting stage of the device.

In the example of the manufacturing method, an example of using the electron beam vapor deposition method for the deposition of various kind of metal films is shown. However, with the use of a sputtering method or the like, the surface planarity of the metal film can be improved to decrease the deviation of the device within the wafer.

In the example described above, the metal film mainly comprising Au is used. With use of other elements such as Al and Cu, the material cost can be reduced.

The example of using the ion milling method is shown for the fabrication of the membrane. It will be apparent that a fabrication method optimal to the metal material, such as a chemical dry etching method, wet etching method, or lift off method may also be used.

In the example of the manufacturing method described above, the film thickness of the membrane is 2.5 micrometers. As shown in the embodiments, the film thickness is preferably set such that curvature in each metal material does not occurs. The optimal film thickness varies depending on the deposition method. Thus, the film thickness is not limited.

The example of manufacturing the membrane made of Au of large film thickness by the electron beam vapor deposition was shown. The thick Au film may also be formed by using an electrolytic Au plating and the like over Au formed as a thin film.

The material cost can be decreased by using an electrolytic Au plating method of applying plating only to a desired region by patterning using a photoresist or the like.

In the manufacture of the membrane using Au, while the example of depositing to form only Au directly is shown in the manufacturing method described above, adhesion can be improved by disposing chromium, molybdenum, etc. as well as titanium of about several nm to several tens nm as an adhesive layer with adjacent layers.

For the patterning of the floating metal as a main constituent element of the present invention, while the example of forming using patterning and the lift off process according to a multi-layered resist technology is shown, it will be apparent that chemical dry etching or wet etching method, etc. may also be used in the case of using other methods for Al and the like.

For the dielectric film, an aluminum film is used by the sputtering method in the example described above. Other methods generally used in semiconductor manufacturing steps such as a CVD method may also be used for the deposition method.

For the material of the dielectric film, any solid material having a dielectric constant that is at least excellent in the insulative property such as a silicon oxide film, silicon nitride film, or tantalum oxide may be applied in addition to the alumina film. Further, instead of a single film, a lamination film of the dielectric material may also be used. As the dielectric constant is higher, the reduction in the size of the device can be easily realized, improving the electric characteristics when the membrane is positioned downward.

For the sacrificial layer 51, a standard polyimide film is used for the sacrificial layer 51 in the example described above. A polyimide film having photosensitivity can facilitate the coating of the photoresist. This has a merit to simplify the process. Further, only normal photoresist may be used for the sacrificial layer as long as this does not cause any problem on heat resistance, etc.

The capacitance type MEMS device of the invention manufactured by the manufacturing method described above is different from the conventional devices with respect to the structure in that the area ratio of the floating method relative to the opposed region is restricted and that the floating metal is connected through a material acting as a resistance relative to high frequency signals with a material having a desired potential with respect to DC voltage. So far as the manufacturing process is concerned, it is apparent that the invention can provide excellent device characteristics with the small increase of processes. That is, in the case of manufacturing the capacitance type MEMS device according to the invention in accordance with the manufacturing method described above, a capacitance type MEMS device having extremely favorable switching characteristics relative to high frequency signals can be provided with the manufacture cost reduced.

Main embodiments of the present invention are described below.

(1) A capacitance type MEMS device including at least:

a substrate,

anchors formed on the substrate,

springs in contiguous with the anchors,

an upper electrode that is in contiguous with the springs and moves above the substrate while giving elastic deformation to the springs,

a lower electrode formed below the upper electrode, having a region opposed to at least a portion of the upper electrode and formed above the substrate,

a dielectric film formed both on a portion of the substrate and on a portion of the lower electrode to cover at least a region larger than the upper electrode as viewed in the direction perpendicular to the substrate, and

a metal film of low resistance formed in contact with a portion of the dielectric film formed on the lower electrode opposed to at least a portion of the upper electrode, wherein

when a DC voltage is applied between the upper electrode and the lower electrode, the upper electrode is attracted downward by an electrostatic force generated between the opposing upper electrode and the lower electrode, a portion of the upper electrode is in contact with a portion of the metal film of low resistance, and the upper electrode and the metal film of low resistance are connected electrically, thereby forming a capacitor structure comprising the upper electrode connected through the metal film of low resistance, the dielectric film, and the lower electrode, wherein

a region where the dielectric film and the metal film of low resistance are laminated and a region where only the dielectric film is formed are present together above the lower electrode in a region where the upper electrode and the lower electrode are opposed, and the area of the region where the dielectric film and the metal film of low resistance are laminated in the region where the upper electrode and the lower electrode are opposed is equal to or smaller than the area of the region where the dielectric film is exposed in the region described above as viewed in the direction perpendicular to the substrate.

(2) A capacitance type MEMS device including at least:

a substrate,

anchors formed on the substrate,

springs in contiguous with the anchors,

an upper electrode that is in contiguous with the springs and moves above the substrate while giving elastic deformation to the springs,

a lower electrode formed below the upper electrode, having a region opposed to at least a portion of the upper electrode and formed above the substrate,

a dielectric film formed both on a portion of the substrate and on a portion of the lower electrode to cover at least a region larger than the upper electrode as viewed in the direction perpendicular to the substrate, and

a metal film of low resistance formed in contact with a portion of the dielectric film formed on the lower electrode opposed to at least a portion of the upper electrode, wherein

the metal film of low resistance is connected with a material having a desired potential with respect to direct current through a material acting as a resistance relative to high frequency signals.

(3) A capacitance type MEMS device according to the paragraph (2) above, wherein the material acting as a resistance relative to high frequency signals is a material showing an electric resistance value of at least 1 kΩ or more and less than 1 MΩ.

(4) A capacitance type MEMS device according to the paragraph (2) above, wherein the material acting as a resistance relative to the high frequency signals is an inductor showing an impedance of at least 1 kΩ or more and less than 1 MΩ relative to high frequency signals.

(5) A capacitance type MEMS device according to the paragraph (2) above, wherein the material having the desired potential is the upper electrode.

(6) A capacitance type MEMS device according to the paragraph (2) above, wherein the material having the desired potential is the lower electrode.

(7) A capacitance type MEMS device according to the paragraph (2) above, wherein the material having the desired potential is a ground region (earth).

(8) A capacitance type MEMS device according to the paragraph (2) above, wherein the material having the desired potential is a control electrode for controlling the vertical movement of the upper electrode by applying a DC voltage.

(9) A capacitance type MEMS device according to the paragraph (1) above, wherein the region where only the dielectric film according to claim 1 is formed by an opening portion having a predetermined shape in the metal film of low resistance.

(10) A capacitance type MEMS device according to the paragraph (1) or (2) above, wherein the spring, the anchor, and the upper electrode form an integral structure made of a continuous metal member.

(11) A capacitance type MEMS device according to the paragraph (8) above, wherein the metal member comprises a single layered film at least containing aluminum or a lamination film containing an aluminum-containing film and other metal films.

(12) A capacitance type MEMS device according to the paragraph (8) above, wherein the metal member comprises a single layered film at least containing gold, or a lamination film of a gold-containing film and other metal films.

(13) A capacitance type MEMS device according to the paragraph (8) above, wherein the metal member comprises a single layered film at least containing copper or a lamination film of a copper-containing film and other metal films.

(14) A capacitance type MEMS device according to the paragraph (1), (2) above, wherein the metal film of low resistance comprises a single layered film at least containing aluminum, or a lamination film of an aluminum-containing film and other metal films.

(15) A capacitance type MEMS device according to the paragraph (1), (2) above, wherein the metal film of low resistance comprises a single layered film at least containing gold, or a lamination film of a gold-containing film and other metal films.

(16) A capacitance type MEMS device according to the paragraph (1), (2) above, wherein the metal film of low resistance comprises a single layered film at least containing copper, or a lamination film of a copper-containing film and other metal films.

(17) A capacitance type MEMS device according to any one of paragraphs (1) to (14) above, wherein the metal film of low resistance is a floating metal that is not connected relative to high frequency signals when voltage is not applied between the upper electrode and the lower electrode.

(18) A high frequency device in which the capacitance type MEMS device according to any one of paragraphs (1) to (15) is mounted on an on/off switch for high frequency signals.

(19) A high frequency device in which the capacitance type MEMS device according to any one of paragraphs (1) to (15) is mounted on an output changing switch for high frequency signals.

(20) A high frequency device in which the capacitance type MEMS device according to any one of paragraphs (1) to (15) is mounted on a high frequency filter module for mobile telephones.

(22) A high frequency device in which the capacitance type MEMS device according to any one of paragraphs (1) to (15) is mounted together with an active device on one substrate.

(23) A high frequency device in which the capacitance type MEMS device according to any one of paragraphs (1) to (15) is mounted together with other passive device on one substrate.

(24) A method of manufacturing a capacitance type MEMS device at least including

a substrate,

anchors formed on the substrate,

springs in contiguous with the anchors,

an upper electrode that is in contiguous with the springs and moves above the substrate while giving elastic deformation to the springs,

a lower electrode formed below the upper electrode, having a region opposed to at least a portion of the upper electrode and formed above the substrate,

a dielectric film formed both on a portion of the substrate and on a portion of the lower electrode to cover at least a region larger than the upper electrode as viewed in the direction perpendicular to the substrate, and

a metal film of low resistance formed in contact with a portion of the dielectric film formed on the lower electrode opposed to at least a portion of the upper electrode, in which

a region where the dielectric film and the metal film of low resistance are laminated and a region where only the dielectric film is formed are present together above the lower electrode in a region where the upper electrode and the lower electrode are opposed, and the area of the region where the dielectric film and the metal film of low resistance are laminated in the region where the upper electrode and the lower electrode are opposed is equal to or smaller than the area of the region where the dielectric film is exposed in the region described above as viewed in the direction perpendicular to the substrate, the method including:

a step of forming the lower electrode pattern made of the metal film on the substrate,

a step of forming a pattern made of the dielectric film at a desired region on the substrate and on the upper surface of the lower electrode,

a step of forming a pattern made of the metal film of low resistance having a desired shape at a desired region where the lower electrode and the dielectric film above the substrate are laminated,

a step of forming a pattern made of a sacrificial film having a desired shape above the substrate where the lower electrode, the dielectric film, and the metal film of low resistance are formed,

a step of depositing and fabricating a metal film at a desired position above the substrate and the sacrificial film pattern, thereby forming the anchors, the springs, and the upper electrode in an integral structure, and

a step of removing the sacrificial film.

(25) A method of manufacturing a capacitance type MEMS device according to the paragraph (20) above, which includes a step of forming a pattern made of a material showing a desired electric resistance value to a desired position above the substrate.

(26) A method of manufacturing a capacitance type MEMS device according to the paragraph (20) above, which includes a step of forming a pattern made of a material showing a desired impedance value to a desired position above the substrate.

Main references related to the drawings are shown below.
1 signal line
2 earth
3 insulative substrate
5 dielectric film
6 floating metal
7 resistance element
8 membrane
10 anchor
11 spring
12 upper electrode
13 signal line
14 earth
15 Si substrate
16 cantilever
17 anchor
18 spring
19 upper electrode
20 dielectric film
21 floating metal
22 resistance element
24 input signal line
25 output signal line on the left
26 output signal line on the right
27 earth
28 glass substrate
29 membrane
30 anchor
31 first spring
32 second spring
33 upper electrode on the left
34 upper electrode on the right
35 dielectric film
36 floating metal on the left
37 floating metal on the left
38 inductance element on the left
39 inductance element on the right
41 input signal line
41 output signal line
42 earth
43 Si substrate
44 membrane
45 anchor
46 spring
47 upper electrode
48 dielectric film
49 floating metal
50 protrusion
51 sacrificial layer
52 high frequency switch
53 input terminal
54 output terminal
55 control terminal
56 input terminal
57 output terminal on the left
58 output terminal on the right
59 control terminal
60 glass substrate
61 signal line
61 earth
63 control terminal
64 membrane
65 anchor
66 spring
67-1 region for generating electrostatic force relative to earth 62
67-2 region in contact with floating metal
67 upper electrode
69 dielectric film
70 floating metal
71 inductance element
72 high frequency switch
73 input terminal
74 output terminal
75 control terminal
91 substrate
92 receiving system
93 transmission system
94 high frequency filter
95 capacitance type MEMS device of the invention
96 antenna

### INDUSTRIAL APPLICABILITY

The device according to the present invention can be used as a switch device for electric signals. Particularly, the present invention is useful for high frequency signals and can provide a high frequency device using the device described above. Further, the present invention can provide a method of manufacturing such a device.

1. A capacitance type MEMS device comprising:
a substrate;
a lower electrode formed on the substrate;
a dielectric film formed on the lower electrode;
a conductor layer formed on the dielectric layer; and
an upper electrode opposed to the lower electrode and disposed at least with a gap relative to the conductor layer formed on the dielectric layer and controlled whether the upper electrode is in contact or non-contact with the conductor control layer formed on the dielectric layer;
wherein the conductor layer formed on the dielectric layer is formed in a region where the upper electrode and the lower electrode are opposed such that a conductor layer formed on the dielectric layer is present in a portion of the opposed area as viewed in the direction perpendicular to the substrate, and
wherein the area of the region where the conductor layer formed on the dielectric layer is present in the region where the upper electrode and the lower electrode are opposed is equal to or smaller than the area of the region where the conductor layer formed on the dielectric layer is not present in the opposed region.

2. A capacitance type MEMS device comprising:
a substrate;
a lower electrode formed on the substrate;
a dielectric film formed on the lower electrode;
a conductor layer formed on the dielectric layer; and
an upper electrode opposed to the lower electrode and disposed at least with a gap relative to the conductor layer formed on the dielectric layer and controlled whether the upper electrode is in contact or non-contact with the conductor layer formed on the dielectric layer;
wherein the conductor layer formed on the dielectric layer is connected through a resistor relative to high frequency signals to a desired potential with respect to direct current.

3. A capacitance type MEMS device according to claim 2, wherein the resistor relative to the high frequency signals is a material showing an electric resistance value of at least 1 kΩ or more and less than 1 MΩ.

4. A capacitance type MEMS device according to claim 2, wherein the resistor relative to the high frequency signals is an inductor showing an impedance of at least 1 kΩ or more and less than 1 MΩ.

5. A capacitance type MEMS device according to claim 2, wherein the desired potential is provided by connection with respect to direct current of the conductor formed on the dielectric layer to one of the upper electrode, the lower electrode, the control electrode, and the ground region.

6. A capacitance type MEMS device according to claim 1, wherein the conductor layer formed on the dielectric layer has an opening.

7. A capacitance type MEMS device according to claim 1, wherein the conductor layer formed on the dielectric layer is made of a single layered film at least containing aluminum or a plurality of metal lamination films including an aluminum-containing film.

8. A capacitance type MEMS device according to claim 2, wherein the conductor layer formed on the dielectric layer is made of a single layered film at least containing aluminum or a plurality of metal lamination films including an aluminum-containing film.

9. A capacitance type MEMS device according to claim 1, wherein the conductor layer formed on the dielectric layer is made of a single layered film at least containing gold or a plurality of metal lamination films including a gold-containing film.

10. A capacitance type MEMS device according to claim 2, wherein the conductor layer formed on the dielectric layer is made of a single layered film at least containing gold or a plurality of metal lamination films including a gold-containing film.

11. A capacitance type MEMS device according to claim 1, wherein the conductor layer formed on the dielectric layer is made of a single layered film at least containing copper or a plurality of metal lamination films including a copper-containing film.

12. A capacitance type MEMS device according to claim 2, wherein the conductor layer formed on the dielectric layer is made of a single layered film at least containing copper or a plurality of metal lamination films including a copper-containing film.

13. A high frequency device in which the capacitance type MEMS device according to claim 1 is provided as an on/off switch for high frequency signals.

14. A high frequency device in which the capacitance type MEMS device according to claim 1 is provided as an output changing switch for high frequency signals.

15. A high frequency device in which the capacitance type MEMS device according to claim 1 is provided as a high frequency filter module for mobile telephones.

16. A high frequency device in which the capacitance type MEMS device according to claim 1, an active device, a passive device, or both of the active device and the passive device are mounted on one substrate.

17. A method of manufacturing a capacitance type MEMS device, comprising:
a step of forming a lower electrode disposed on a substrate;
a step of forming a dielectric film at a desired position on the substrate and on the upper surface of the lower electrode;
a step of forming a conductor layer pattern at a desired position of a region where the lower electrode and the dielectric film above the substrate are laminated;
a step of forming a sacrificial film over the substrate formed with the lower electrode, the dielectric film, and the metal film of low resistance;
a step of forming an upper electrode on the substrate and on the sacrificial film at a position opposed to the lower electrode; and
a step of removing the sacrificial film.
